(19) United States
(12) Patent Application Publication
(10) Pub. No.: US 2023/0067860 A1
(43) Pub. Date: Mar. 2, 2023

(54) SEMICONDUCTOR MEMORY DEVICE

(71) Applicant: SK hynix Inc., Icheon-si Gyeonggi-do (KR)

(72) Inventors: Dong Hwan LEE, Icheon-si Gyeonggi-do (KR); Seo Hyun KIM, Icheon-si Gyeonggi-do (KR)

(73) Assignee: SK hynix Inc., Icheon-si Gyeonggi-do (KR)

(21) Appl. No.: 17/682,860

(22) Filed: Feb. 28, 2022

(30) Foreign Application Priority Data
Aug. 27, 2021 (KR) 10-2021-0114199

(51) Int. Cl. H01L 27/11573; H01L 27/11582; H01L 23/522; G11C 16/04; G11C 16/08

(52) U.S. Cl. CPC H01L 27/11573; H01L 27/11582; H01L 23/5226; G11C 16/0483; G11C 16/08; H01L 2224/08146; H01L 24/08

(57) ABSTRACT

A semiconductor memory device includes a semiconductor substrate including a first circuit group and a second circuit group spaced apart from each other. The memory device also includes a memory cell array overlapping with the semiconductor substrate. The memory device further includes a vertical conductive line crossing the memory cell array, the vertical conductive line being connected to the first circuit group and the second circuit group.

### CROSS-REFERENCE TO RELATED APPLICATION

The present application claims priority under 35 U.S.C. § 119(a) to Korean patent application number 10-2021-0114199 filed on Aug. 27, 2021, in the Korean Intellectual Property Office, the entire disclosure of which is incorporated by reference herein.

### BACKGROUND

### 1. Technical Field

Various embodiments of the present disclosure generally relate to a semiconductor memory device, and more particularly, to a three-dimensional semiconductor memory device.

### 2. Related Art

A semiconductor memory device may include a memory cell array and a peripheral circuit structure. The memory cell array may include a plurality of memory cells capable of storing data. The peripheral circuit structure may be configured to control various operations of the memory cell.

A memory cell array of a three-dimensional memory device may include a plurality of three-dimensionally arranged memory cells. Accordingly, the two-dimensional area occupied by the memory cells over a substrate can be reduced, and the degree of integration of the semiconductor memory device can be improved. In order to improve efficiency per unit area of the substrate, a peripheral circuit structure may overlap with a memory cell array. Lines for electrically connecting the memory cell array to the peripheral circuit structure may become a factor which limits miniaturization of the semiconductor memory device.

### SUMMARY

In accordance with an embodiment of the present disclosure, a semiconductor memory device includes: a first gate stack structure and a second gate stack structure, including a first conductive pattern and a second conductive pattern, the first conductive pattern spaced apart from the second conductive pattern, the first gate stack structure adjacent to the second gate stack structure; a vertical conductive line disposed adjacent to the first gate stack structure and the second gate stack structure; and a semiconductor substrate extending to overlap with the first gate stack structure, the second gate stack structure, and the vertical conductive line. The semiconductor substrate includes a plurality of pass transistors connected to the first and second conductive patterns of at least one of the first gate stack structure and the second gate stack structure. The vertical conductive line is connected to a plurality of gate electrodes of the plurality of pass transistors.

In accordance with another embodiment of the present disclosure, a semiconductor memory device includes: a semiconductor substrate including a peripheral circuit structure; a vertical conductive line disposed over the semiconductor substrate, the vertical conductive line extending in a first direction on a plane parallel to the semiconductor substrate, the vertical conductive line being connected to the peripheral circuit structure; a vertical insulating layer extending on a sidewall of the vertical conductive line; and a first gate stack structure and a second gate stack structure, adjacent to each other in a second direction intersecting the vertical conductive line. The vertical conductive line and the vertical insulating layer are disposed between the first gate stack structure and the second gate stack structure. Each of the first gate stack structure and the second gate stack structure includes a plurality of interlayer insulating layers and a plurality of conductive patterns, which are alternately stacked over the semiconductor substrate.

In accordance with still another embodiment of the present disclosure, a semiconductor memory device includes: a semiconductor substrate including a first circuit group and a second circuit group, which are spaced apart from each other; a memory cell array overlapping with the semiconductor substrate; a vertical conductive line crossing the memory cell array, the vertical conductive line overlapping with the semiconductor substrate; a plurality of first conductive bonding patterns disposed at a level between the semiconductor substrate and the memory cell array, the plurality of first conductive bonding patterns being respectively connected to the first circuit group and the second circuit group; and a plurality of second conductive bonding patterns disposed at a level between the plurality of first conductive bonding patterns and the memory cell array, the plurality of second conductive bonding patterns being connected to the vertical conductive line and the memory cell array, the plurality of second conductive bonding patterns being bonded to the plurality of first conductive bonding patterns. The vertical conductive line is commonly connected to the first circuit group and the second circuit group via parts of the plurality of first conductive bonding patterns and parts of the plurality of second conductive bonding patterns.

### BRIEF DESCRIPTION OF THE DRAWINGS

Example embodiments will now be described more fully hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or additional intervening elements may also be present. Like reference numerals refer to like elements throughout.

FIG. 1 is a block diagram illustrating a semiconductor memory device in accordance with an embodiment of the present disclosure.

FIGS. 2A and 2B illustrate circuit diagrams of switching circuit groups and a memory cell array in accordance with embodiments of the present disclosure.

FIG. 3 is a block diagram illustrating a multi-plane structure in accordance with an embodiment of the present disclosure.

FIG. 4 is a perspective view schematically illustrating a semiconductor memory device in accordance with an embodiment of the present disclosure.

FIGS. 5A to 5D are sectional views illustrating an example configuration of the semiconductor memory device shown in FIG. 4.

FIGS. 6A to 6D, 7A to 7D, 8A to 8B, 9A to 9D, 10A to 10D, 11A to 11D, and 12A to 12D are process sectional views illustrating an embodiment of a manufacturing method of the semiconductor memory device shown in FIGS. 5A to 5D.

FIG. 13 is a block diagram illustrating a configuration of a memory system in accordance with an embodiment of the present disclosure.

FIG. 14 is a block diagram illustrating a configuration of a computing system in accordance with an embodiment of the present disclosure.

### DETAILED DESCRIPTION

The specific structural and functional descriptions disclosed herein are merely illustrative for the purpose of describing embodiments according to the concept of the present disclosure. Additional embodiments according to the concept of the present disclosure can be implemented in various forms. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

Embodiments provide a semiconductor memory device capable of decreasing the size thereof.

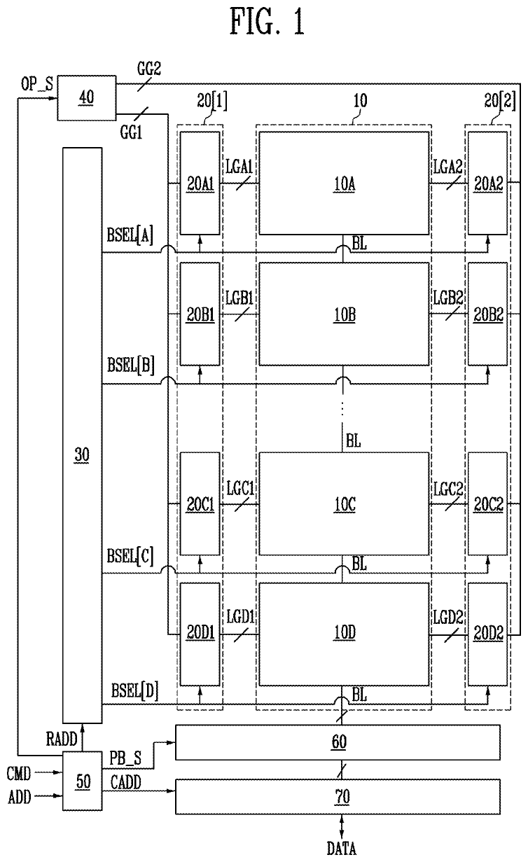

FIG. 1 is a block diagram illustrating a semiconductor memory device in accordance with an embodiment of the present disclosure.

Referring to FIG. 1, the semiconductor memory device may include a memory cell array 10 and a peripheral circuit structure 20[1], 20[2], 30, 40, 50, 60, and 70. The peripheral circuit structure may include a plurality of circuit groups 20[1], 20[2], 30, 40, 50, 60, and 70.

The plurality of circuit groups 20[1], 20[2], 30, 40, 50, 60, and 70 of the peripheral circuit structure may include a first circuit group (e.g. 20[1]) and a second circuit group (e.g., 20[2]) disposed at both sides of the memory cell array 10, and a third circuit group (e.g., 30) configured to commonly control the first circuit group and the second circuit group. Each of the first circuit group and the second circuit group may be connected to the third circuit group through a vertical conductive line (e.g., BSEL[A] to BSEL[D]) disposed across the memory cell array 10. A plurality of transistors constituting the third circuit group (e.g., 30) are not distributedly disposed to be adjacent to each of the first circuit (e.g., 20[1]) and the second circuit group (e.g., 20[2]), but may be disposed in a continuous region. In accordance with the embodiment of the present disclosure, the area occupied by the third circuit group and lines connected thereto may be narrowed as compared with a case where the plurality of transistors of the third circuit group are distributedly disposed in regions spaced apart from each other. Thus, the structure in accordance with the embodiment of the present disclosure may be advantageous in reducing the size of the semiconductor memory device.

The plurality of circuit groups of the peripheral circuit structure may include a first switching circuit group 20[1], a second switching circuit group 20[2], a row decoder 30, a voltage generating circuit 40, a control circuit 50, a page buffer 60, and a column decoder 70.

In an embodiment, the first switching circuit group 20[1] may be the above-described first circuit group, the second switching circuit group 20[2] may be the above-described second circuit group, and the row decoder 30 may be the above-described third circuit group. Hereinafter, drawings are shown based on an embodiment in which the first circuit group, the second circuit group, and the third circuit group respectively correspond to the first switching circuit group 20[1], the second switching circuit group 20[2], and the row decoder 30, which will be described in detail. However, embodiments of the present disclosure are not limited thereto.

The memory cell array 10 may include a plurality of memory blocks 10A to 10D. Each of the memory blocks 10A to 10D may include a plurality of memory cell strings. Each memory cell string may include a plurality of memory cells in which data is stored. Each memory cell may store single-bit data or multi-bit data of two or more bits.

The memory cell array 10 may be connected to the first switching circuit group 20[1] through a plurality of first local lines LGA1, LGB1, LGC1, and LGD1, and be connected to the second switching circuit group 20[2] through a plurality of second local lines LGA2, LGB2, LGC2, and LGD2. The plurality of first local lines LGA1, LGB1, LGC1, and LGD1 and the plurality of second local lines LGA2, LGB2, LGC2, and LGD2 may be configured as conductive patterns stacked on the first switching circuit group 20[1] and the second switching circuit group 20[2] to be spaced apart from each other. The memory cell array 10 may be connected to the page buffer 60 through a plurality of bit line BL.

The control circuit 50 may output an operation signal OP_S, a row address RADD, a page buffer control signal PB_S, and a column address CADD in response to a command CMD and an address ADD.

The voltage generating circuit 40 may output operating voltages necessary for a program operation, a verify operation, a read operation, or an erase operation to a plurality of first global lines GG1 and a plurality of second global line GG2 in response to the operation signal OP_S of the control circuit 50.

The row decoder 30 may output a plurality of block select signals BSEL[A] to BSEL[D] for selecting at least one memory block among the plurality of memory blocks 10A to 10D in response to the row address RADD of the control circuit 50.

The column decoder 70 may transmit data DATA input from an input/output circuit (not shown) to the page buffer 60 or transmit data DATA stored in the page buffer 60 to the input/output circuit (not shown) in response to the column address CADD. The column decoder 70 may exchange data DATA with the page buffer 60.

The page buffer 60 may temporarily store data DATA received through the bit line BL in response to the page buffer control signal PB_S. The page buffer 60 may sense a voltage or current of the bit line BL in a read operation.

The first switching circuit group 20[1] and the second switching circuit group 20[2] may transfer the operating voltages output to the plurality of first global lines GG1 and the plurality of second global lines GG2 to the first local lines and the second local lines in response to the plurality of block select signals BSEL[A] to BSEL[D] output from the row decoder 30.

The configuration of the first switching circuit group 20[1], the configuration of the plurality of first local lines LGA1, LGB1, LGC1, and LGD1, the configuration of the second switching circuit group 20[2], the configuration of the plurality of second local lines LGA2, LGB2, LGC2, and LGD2, the connection relationship between the first switching circuit group 20[1] and the memory cell array 10, and the connection relationship between the second switching circuit group 20[2] and the memory cell array 10 may be various. In an embodiment, the first switching circuit group 20[1] may include a plurality of first sub-switching circuit groups 20A1 to 20D1, and the second switching circuit group 20[2] may include a plurality of second sub-switching circuit groups 20A2 to 20D2. The first sub-switching circuit groups 20A1 to 20D1 may be individually connected to the plurality of memory blocks 10A to 10D, and the second sub-switching circuit groups 20A2 to 20D2 may be individually connected to the plurality of memory blocks 10A to 10D. For example, a first memory block 10A may be connected to a first sub-switching circuit group 20A1 and a second sub-switching circuit group 20A2, which correspond thereto, and a second memory block 10B may be connected to a first sub-switching circuit group 20B1 and a second sub-switching circuit group 20B2, which correspond thereto.

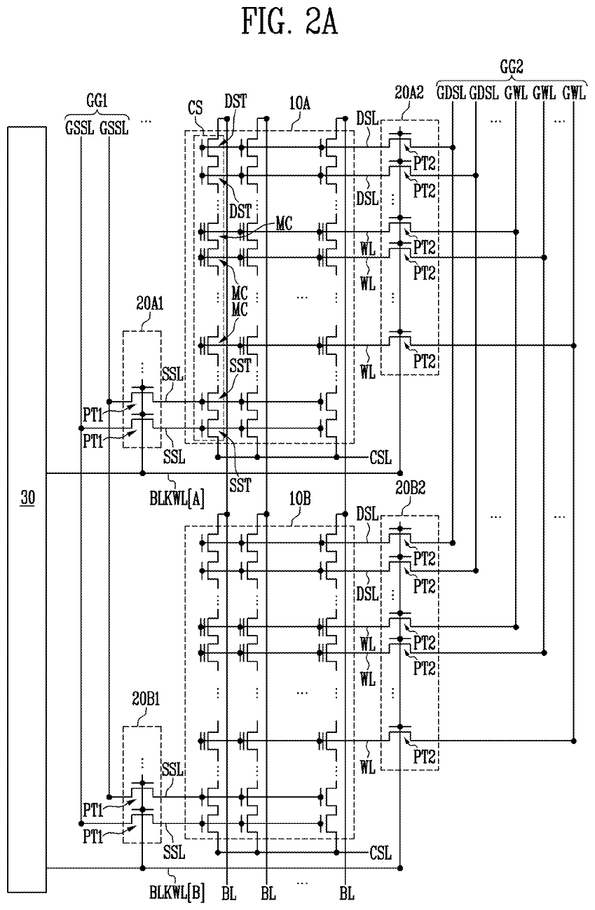

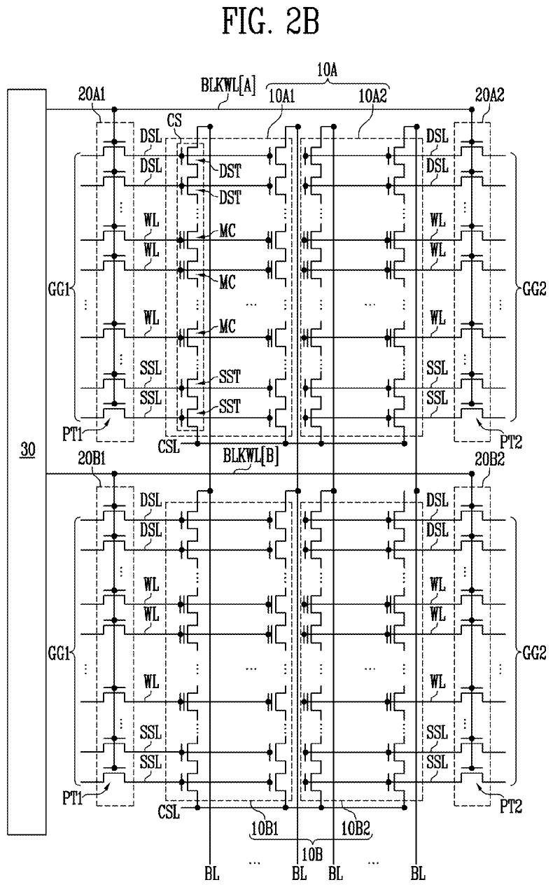

FIGS. 2A and 2B illustrate circuit diagrams of switching circuit groups and a memory cell array in accordance with embodiments of the present disclosure. For example, circuit diagrams of the first memory block 10A, the first and second sub-switching circuit groups 20A1 and 20A2 connected to the first memory block 10A, the second memory block 10B, and the first and second sub-switching circuit groups 20B1 and 20B2 connected to the second memory block 10B, which are described with reference to FIG. 1, in accordance with first and second embodiments of the present disclosure are respectively illustrated in FIGS. 2A and 2B.

Referring to FIGS. 1, 2A and 2B, each of the memory blocks 10A to 10D may include a plurality of memory cell strings CS connected to a plurality of bit lines BL and a common source line CSL. Each memory cell string CS may include at least one drain select transistor DST, a plurality of memory cells MC, and at least one source select transistor SST, which are connected in series. The at least one drain select transistor DST may be connected between the plurality of memory cells MC and a bit line BL. Hereinafter, an embodiment is described based on a structure in which two drain select transistors DST are connected in series between the plurality of memory cells MC and the bit line BL, but the present disclosure is not limited thereto. The at least one source select transistor SST may be connected between the plurality of memory cells MC and the common source line CSL. Hereinafter, an embodiment is described based on a structure in which two source select transistors SST are connected in series between the plurality of memory cells MC and the common source line CSL, but the present disclosure is not limited thereto.

Each memory cell string CS may be connected to at least one drain select line DSL, a plurality of word lines WL, and at least one source select line SSL. The drain select line may be connected to a gate of the drain select transistor DST, the plurality of word lines WL may be connected to gates of the plurality of memory cells MC, and the source select line SSL may be connected to a gate of the source select transistor DST. Hereinafter, an embodiment is described based on a structure in which two drain select lines DSL individually connected to gates of two drain select transistors DST and two source select lines SSL individually connected to gates of two source select transistors SST are connected to each memory cell string CS, but the present disclosure is not limited thereto.

The configuration of the plurality of first local lines LGA1, LGB1, LGC1, and LGD1 and the plurality of second local lines LGA2, LGB2, LGC2, and LGD2 may be various. The first local lines LGA1, LGB1, LGC1, and LGD1 may be connected to the first sub-switching circuit groups 20A1 to 20D1 for each group, and the second local lines LGA2, LGB2, LGC2, and LGD2 may be connected to the second sub-switching circuit groups 20A2 to 20D2 for each group.

Referring to FIGS. 1 and 2A, in the first embodiment, a plurality of memory cell strings CS of each of the memory blocks 10A to 10D may be connected to each other by each of source select lines SSL, a plurality of word lines WL, and drain select lines DSL.

The plurality of first local lines LGA1, LGB1, LGC1, and LGD1 may serve as source select lines SSL of the plurality of memory blocks 10A, 10B, 10C, and 10D. The plurality of first local lines LGA1, LGB1, LGC1, and LGD1 may be divided into groups corresponding to each memory block 10A, 10B, 10C, or 10D. For example, source select lines SSL of the first memory block 10A may constitute first local lines LGA1 of a first group, and source select lines SSL of the second memory block 10B may constitute first local lines LGB1 of a second group. Each group of the plurality of first local lines LGA1, LGB1, LGC1, and LGD1 may be connected to a first sub-switching circuit group 20A1, 20B1, 20C1, or 20D1 corresponding thereto. For example, the source select lines SSL of the first memory block 10A, which constitute the first local lines LGA of the first group, may be connected to the first sub-switching circuit group 20A1, and the source select lines SSL of the second memory block 106, which constitute the first local lines LGB1 of the second group, may be connected to the first sub-switching circuit group 20B1.

The plurality of second local lines LGA2, LG62, LGC2, and LGD2 may serve as a plurality of word lines WL and drain select lines DSL of the plurality of memory blocks 10A, 106, 10C, and 10D. The plurality of second local lines LGA2, LG62, LGC2, and LGD2 may be divided into groups corresponding to each memory block 10A, 106, 10C, or 10D. For example, a plurality of word lines WL and drain select lines DSL of the first memory block 10A may constitute second local lines LGA2 of a first group, and a plurality of word lines WL and drain select lines DSL of the second memory block 106 may constitute second local lines LGB2 of a second group. Each group of the plurality of second local lines LGA2, LG62, LGC2, and LGD2 may be connected to a second sub-switching circuit group 20A2, 2062, 20C2, or 20D2 corresponding thereto. For example, the plurality of word lines WL and the drain select lines DSL of the first memory block 10A, which constitute the second local lines LGA2 of the first group, may be connected to the second sub-switching circuit group 20A2, and the plurality of word lines WL and the drain select lines DSL of the second memory block 106, which constitute the second local lines LGB2 of the second group, may be connected to the second sub-switching circuit group 2062.

Referring to FIGS. 1 and 2B, in the second embodiment, a plurality of memory cell strings CS of each of the memory blocks 10A to 10D may be divided into a first memory cell string of a first group and a memory cell string of a second group. For example, a plurality of memory cell strings CS1 of the first memory block 10A may be divided into a memory cell string 10A1 of a first group and a memory cell string 10A2 of a second group, and a plurality of memory cell strings CS2 of the second memory block 101J may be divided into a memory cell string 101J1 of a first group and a memory cell string 1062 of a second group.

The plurality of first local lines LGA1, LGB1, LGC1, and LGD1 may serve as source select lines SSL, a plurality of word lines WL, and drain select lines DSL, which are connected to memory cell strings of a first group of the plurality of memory blocks 10A, 10B, 10C, and 10D. The plurality of first local lines LGA1, LGB1, LGC1, and LGD1 may be divided into groups corresponding to each memory block 10A, 10B, 10C or 10D. For example, source select lines SSL, a plurality of word lines WL, and drain select lines DSL, which are connected to the memory cell string 10A1 of the first group of the first memory block 10A, may constitute first local lines LGA1 of a first group, and source select lines SSL, a plurality of word lines WL, and drain select lines DSL, which are connected to the memory cell string 101J1 of the first group of the second memory block 10B, may constitute first local lines LGB1 of a second group. Each group of the plurality of first local lines LGA1, LGB1, LGC1, and LGD1 may be connected to a first sub-switching circuit group 20A1, 20B1, 20C1 or 20D1 corresponding thereto. For example, the source select lines SSL, the plurality of word lines WL, and the drain select lines DSL, which constitute the first local lines LGA1 of the first group of the first memory block 10A, may be connected to the first sub-switching circuit group 20A1. In addition, the source select lines SSL, the plurality of word lines WL, and the drain select lines DSL, which constitute the first local lines LGB1 of the second group of the second memory block 10B, may be connected to the first sub-switching circuit group 20B1.

The plurality of second local lines LGA2, LGB2, LGC2, and LGD2 may serve as source select lines SSL, a plurality of word lines WL, and drain select lines DSL, which are connected to memory cell strings of a second group of the plurality of memory blocks 10A, 10B, 10C, and 10D.

The plurality of second local lines LGA2, LGB2, LGC2, and LGD2 may be divided into groups corresponding to each memory block 10A, 10B, 10C or 10D. For example, the source select lines SSL, the plurality of word lines WL, and the drain select lines DSL, which are connected to the memory cell string 10A2 of the second group of the first memory block 10A, may constitute second local lines LGA2 of a first group, and the source select lines SSL, the plurality of word lines WL, and the drain select lines DSL, which are connected to the memory cell string 1062 of the second group of the second memory block 10B, may constitute second local lines LGB2 of a second group. Each group of the plurality of second local lines LGA2, LG62, LGC2, and LGD2 may be connected to a second sub-switching circuit group 20A2, 2062, 20C2 or 20D2 corresponding thereto. For example, the source select lines SSL, the plurality of word lines WL, and the drain select lines DSL, which constitute the second local lines LGA2 of the first group of the first memory block 10A, may be connected to a second sub-switching circuit group 20A2. In addition, the source select lines SSL, the plurality of word lines WL, the drain select lines DSL, which constitute the second local lines LGB2 of the second group of the second memory block 10B, may be connected to the second sub-switching circuit group 2062.

Referring to FIGS. 1, 2A, and 2B, the first global lines GG1 and the second global lines GG2 may include global lines GSSL, GWL, and GDSL supplying the operating voltages to the plurality of first local lines LGA1, LGB1, LGC1, and LGD1 and the plurality of second local lines LGA2, LG62, LGC2, and LGD2. The global lines GSSL, GWL, and GDSL may include global source select lines GSSL, global word lines WL, and global drain select lines GDSL. The global source select lines GSSL may transmit voltages supplied to the source select lines SSL, the global word lines WL may transmit voltages supplied to the word lines WL, and the global drain select lines GDSL may transmit voltages supplied to the drain select lines DSL.

Each of the first sub-switching circuit groups 20A1 to 20D1 may include first pass transistors PT1. Gates of the first pass transistors PT1 may be commonly connected to a block word line transmitting a block select signal corresponding thereto. For example, gates of first pass transistors PT1 of the first sub-switching circuit group 20A1 connected to the first memory block 10A may be connected to a first block word line BLKWL[A] transmitting a first block select signal BSEL[A], and gates of first pass transistors PT1 of the first sub-switching circuit group 20B1 connected to the second memory block 10B may be connected to a second block word line BLKWL[B] transmitting a second block select signal BSEL[B].

Each of the second sub-switching circuit groups 20A2 to 20D2 may include second pass transistors PT2. Gates of the second pass transistors PT2 may be commonly connected to a block word line transmitting a block select signal corresponding thereto. For example, gates of second pass transistors PT2 of the second sub-switching circuit group 20A2 connected to the first memory block 10A may be connected to the first block word line BLKWL[A] transmitting the first block select signal BSEL[A], and gates of second pass transistors PT2 of the second sub-switching circuit group 20B2 connected to the second memory block 10B may be connected to the second block word line BLKWL[B] transmitting the second block select signal BSEL[B].

As described above, in accordance with the embodiment of the present disclosure, each block word line (e.g., BLKWL[A]) transmitting a block select signal may be commonly connected to the gates of the first pass transistors PT1 of the first switching circuit group 20A1 and the gates of the second pass transistor PT2 of the second switching circuit group 20A2, which correspond thereto.

The memory cell array 10 described with reference to FIGS. 1 and 2A or FIGS. 1 and 2B may constitute a portion of a multi-plane structure.

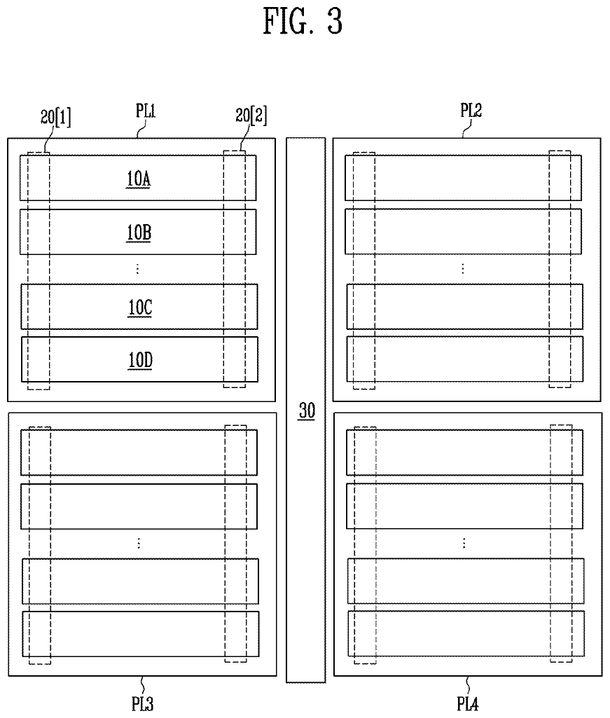

FIG. 3 is a block diagram illustrating a multi-plane structure in accordance with an embodiment of the present disclosure.

Referring to FIG. 3, the multi-plane structure may include two or more planes PL1 to PL4 controlled by the row decoder 30. FIG. 3 exemplifies a multi-plane structure including a first plane PL1, a second plane PL2, a third plane PL3, and a fourth plane PL4, but the present disclosure is not limited thereto.

The first to fourth planes PL1 to PL4 may be disposed on different regions of a semiconductor substrate. Each of the first to fourth planes PL1 to PL4 may include the plurality of memory blocks 10A to 10D described with reference to FIGS. 1 and 2. The memory blocks 10A to 10D may be connected to the first switching circuit group 20[1] and the second switching circuit group 20[2].

The first switching circuit group 20[1] and the second switching circuit group 20[2], which are involved in an operation of each of the first to fourth planes PL1 to PL4, may be controlled by the row decoder disposed in a partial region of the semiconductor memory device, which is adjacent to any one thereof.

The first switching circuit group 20[1] and the second switching circuit group 20[2] may overlap with both ends of each of gate stack structures including local lines of the memory blocks 10A to 10D.

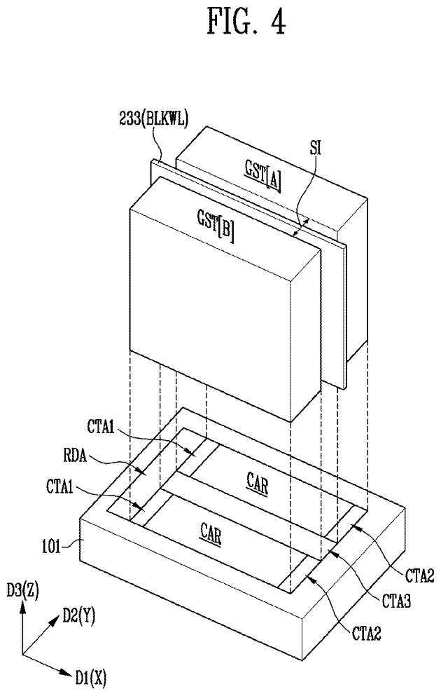

FIG. 4 is a perspective view schematically illustrating a semiconductor memory device in accordance with an embodiment of the present disclosure. For example, an arrangement of a semiconductor substrate 101, a first gate stack structure GST[A], a second gate stack structure GST[B], and a block word line BLKWL is schematically illustrated in FIG. 4. Hereinafter, directions in which axes intersecting each other face on a plane in parallel to a top surface of the semiconductor substrate 10 are defined as a first direction D1 and a second direction D2, and a direction intersecting the top surface of the semiconductor substrate 101 is defined as a third direction D3. For example, the first direction D1, the second direction D2, and the third direction D3 may be directions in which an X axis, a Y axis, and a Z axis of an XYZ coordinate system extend.

Referring to FIG. 4, the semiconductor substrate 101 may include the peripheral circuit structure configured with the first sub-switching circuit groups 20A1 to 20D1 of the first switching circuit group 20[1], the second sub-switching circuit groups 20A2 to 20D2 of the second switching circuit group 20[2], the row decoder 30, the voltage generating circuit 40, the control circuit 50, the page buffer 60, and the column decoder 70, which are shown in at least one of FIGS. 1, 2A, and 2B. The semiconductor substrate 101 may include a row decoder region RDA, a first contact region CTA1, a second contact region CTA2, a third contact region CTA3, and a cell array region CAR. The row decoder 30 shown in at least one of FIGS. 1, 2A, and 2B may be disposed in the row decoder region RDA of the semiconductor substrate 10. Each of the first sub-switching circuit groups 20A1 to 20D1 shown in at least one of FIGS. 1, 2A, and 2B may be disposed in a first contact region CTA1 corresponding thereto. Each of the second sub-switching circuit groups 20A2 to 20D2 shown in at least one of FIGS. 1, 2A, and 2B may be disposed in a second contact region CTA2 corresponding thereto. The cell array region CAR may be defined between the first contact region CTA1 and the second contact region CTA2. The third contact region CTA3 may be defined in the semiconductor substrate 101 between gate stack structures adjacent to each other. For example, the third contact region CTA3 may be defined in the semiconductor substrate 101 between the first gate stack structure GST[A] and the second gate stack structure GST[B].

The row decoder region RDA may face the second contact region CTA2, and the first contact region CTA1 and the cell array region CAR may be disposed between the row decoder region RDA and the second contact region CTA2. The row decoder region RDA may extend to be adjacent to the third contact region CTA3.

Each of the plurality of memory blocks 10A to 10D shown in at least one of FIGS. 1, 2A, and 2B may include at least one gate stack structure. In an embodiment, the first memory block 10A shown in at least one of FIGS. 1, 2A, and 2B may include the first gate stack structure GST[A], and the second memory block 10B shown in at least one of FIGS. 1, 2A, and 2B may include the second gate stack structure GST[B]. However, the present disclosure is not limited thereto, and each memory block may include two or more gate stack structures isolated from each other by a slit SI.

Each of the gate stack structures may include first local lines and second local lines, which are stacked to be spaced apart from each other in the third direction D3. In an embodiment, the first gate stack structure GST[A] may include the source select lines SSL, the word lines WL, and the drain select lines DSL of the first memory block 10A shown in at least one of FIGS. 1, 2A, and 2B, and the second gate stack structure GST[B] may include the source select lines SSL, the word lines WL, and the drain select lines DSL of the second memory block 10B shown in at least one of FIGS. 1, 2A, and 2B.

The slit SI may be defined between the gate stack structures adjacent to each other. The slit SI may be disposed between the first gate stack structure GST[A] and the second gate stack structure GST[B].

A vertical conductive line 233 may be disposed while crossing a memory cell array. In an embodiment, the vertical conductive line 233 may be disposed between the first gate stack structure GST[A] and the second gate stack structure GST[B], and be disposed in the slit SI. The vertical conductive line 233 may be used as the block word line BLKWL transmitting one of the block select signals BSEL[A] to BSEL[D] described with reference to FIG. 1. For example, the block word line BLKWL may transmit the first block select signal BSEL[A] shown in FIG. 1, and be used as the first block word line BLKWL[A] shown in FIGS. 2A and 2B.

The vertical conductive line 233 may extend in the first direction D1. The first gate stack structure GST[A] and the second gate stack structure GST[B] may be adjacent to each other in the second direction D2 intersecting the vertical conductive line 233.

The row decoder region RDA of the semiconductor substrate 101 may not overlap with the first gate stack structure GST[A] and the second gate stack structure GST[B]. The third contact region CTA3 of the semiconductor substrate 101 may overlap with the vertical conductive line 233. The first contact region CTA1 and the second contact region CTA2 of the semiconductor substrate 101 may overlap with both ends of a gate stack structure corresponding thereto. For example, the first gate stack structure GST[A] may include a first end portion and a second end portion spaced apart from the first end portion in the first direction D1. The first contact region CTA1 may overlap with the first end portion of the first gate stack structure GST[A], and the second contact region CTA2 may overlap with the second end portion of the first gate stack structure GST[A].

As described above, the block word line BLKWL may include the vertical conductive line 233 disposed between the first gate stack structure GST[A] and the second gate stack structure GST[B], which are adjacent to each other, so that a separate space for the block word line BLKWL may be removed. Accordingly, the size of the semiconductor memory device may be reduced.

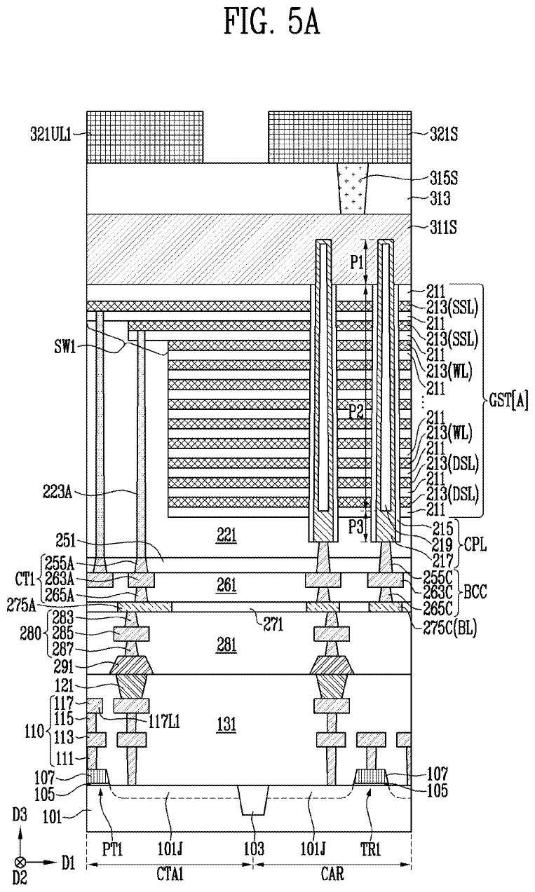

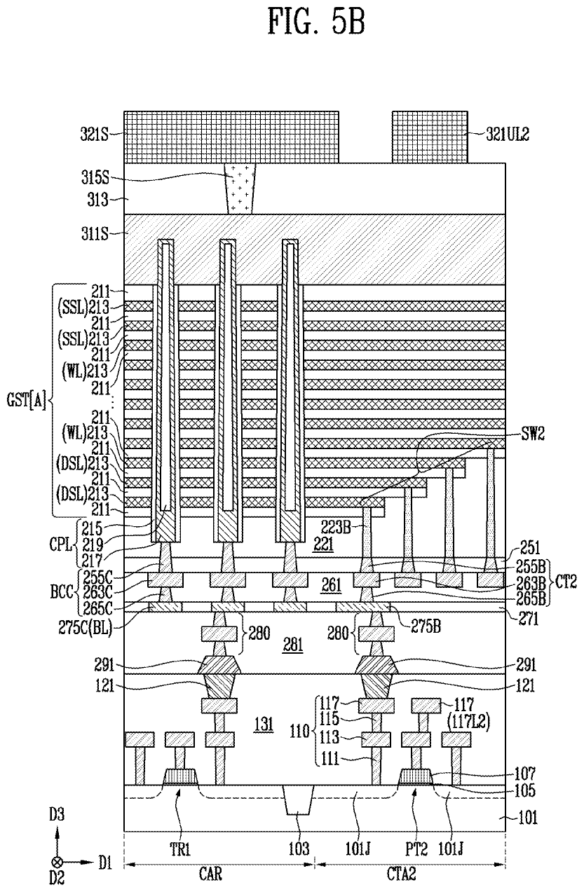

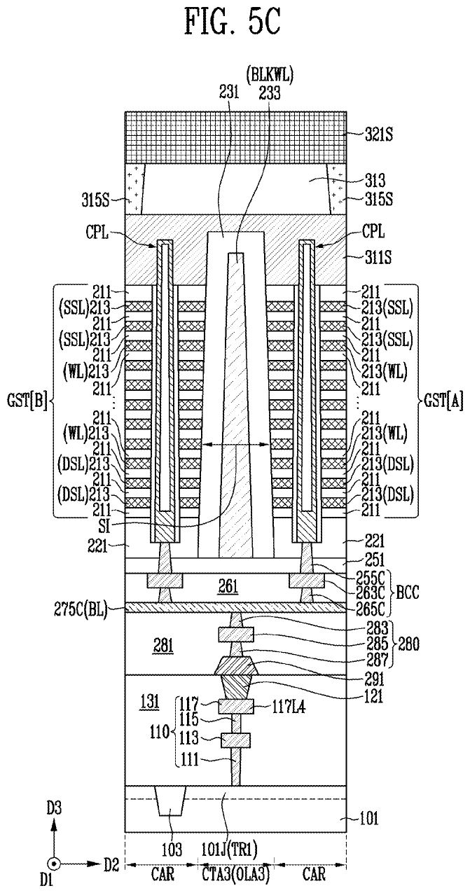

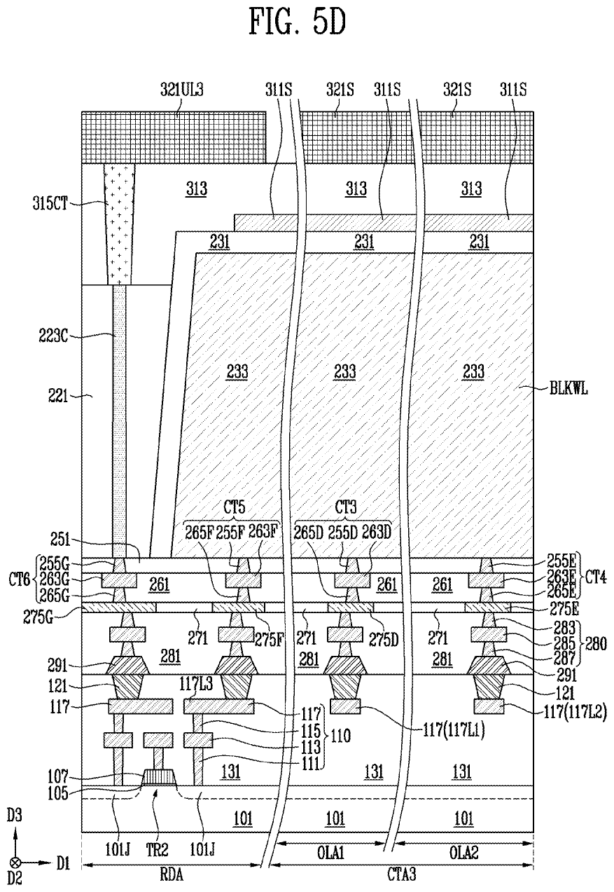

FIGS. 5A to 5D are sectional views illustrating an example configuration of the semiconductor memory device shown in FIG. 4.

FIG. 5A is a sectional view of the first contact region CTA1 of the semiconductor substrate 101 shown in FIG. 4, a portion of the cell array region CAR adjacent to the first contact region CTA1, components overlapping therewith, which are taken along the first direction D1. FIG. 5B is a sectional view of the second contact region CTA2 of the semiconductor substrate 101 shown in FIG. 4, a portion of the cell array region CAR adjacent to the second contact region CTA2, and components overlapping therewith, which are taken along the first direction D1. FIG. 5C is a sectional view of the third contact region CTA3 of the semiconductor substrate 101 shown in FIG. 4, a portion of each of the cell array regions CAR at both sides of the third contact region CTA3, and components overlapping therewith, which are taken along the second direction D2. FIG. 5D is a sectional view of the row decoder region RDA of the semiconductor substrate 101 shown in FIG. 4, a portion of the third contact region CTA3, and components overlapping therewith, which are taken along the first direction D1. A first overlapping region OLA1 shown in FIG. 5D may be defined as a portion of the third contact region CTA3 adjacent to the first contact region CTA1 shown in FIG. 4, a second overlapping region OLA2 shown in FIG. 5D may be defined as a portion of the third contact region CTA3 adjacent to the second contact region CTA2 shown in FIG. 4, and a third overlapping region OLA3 shown in FIG. 5C may be defined as a portion of the third contact region CTA3 adjacent to the cell array region CAR shown in FIG. 4.

Referring to FIGS. 5A to 5D, the semiconductor substrate 101 of the semiconductor memory device may include a peripheral circuit structure. The peripheral circuit structure may include a first pass transistor PT1, a first transistor TR1, a second pass transistor PT2, and a second transistor TR2.

For example, the first pass transistor PT1 may be a component of the first sub-switching circuit group 20A1 of the first switching circuit group 20[1] described with reference to FIGS. 1, 2A, and 3, and the second pass transistor PT2 may be a component of the second sub-switching circuit group 20A2 of the second switching circuit group 20[2] described with reference to FIGS. 1, 2A, and 3. The first transistor TR1 may be a component of the page buffer 60 described with reference to FIG. 1, and the second transistor TR2 may be a component of the row decoder 30 described with reference to FIGS. 1, 2A, and 3.

Each of the first pass transistor PT1, the first transistor TR1, the second pass transistor PT2, and the second transistor TR2 may include a gate insulating layer 105, a gate electrode 107, and junctions 101J. The gate insulating layer 105 and the gate electrode 107 may be stacked on an active region of the semiconductor substrate 101. The active region of the semiconductor substrate 101 may be divided by an isolation layer 103 buried in the semiconductor substrate 101. The junctions 101J may be defined as a region in which at least one of an n-type impurity and a p-type impurity is implanted into the active region of the semiconductor substrate 101 at both sides of the gate electrode 107. The junctions 101J may be provided as a source region and a drain region of a transistor corresponding thereto.

The memory cell array of the semiconductor memory device may overlap with the semiconductor substrate 101. The memory cell array may include the first gate stack structure GST[A] and the second gate stack structure GST[B], which surround a plurality of cell plugs CPL.

The first gate stack structure GST[A] and the second gate stack structure GST[B] may be spaced apart from each other in the second direction D2 by the slit SI. Each of the first gate stack structure GST[A] and the second gate stack structure GST[B] may include a plurality of interlayer insulating layers 211 and a plurality of conductive patterns 213, which are alternately stacked over the semiconductor substrate 101. The plurality of conductive patterns 213 may be insulated from each other by the plurality of interlayer insulating layers 211, and be spaced apart from each other in the third direction D3. For example, the plurality of conductive patterns 213 may include a first conductive pattern and a second conductive pattern and the first conductive pattern may be spaced apart from the second conductive pattern in the third direction D3. The plurality of conductive patterns 213 may constitute drain select lines DSL, word lines WL, and source select lines SSL. The word lines WL may be disposed between the drain select lines DSL and the source select line SSL.

Each of the first gate stack structure GST[A] and the second gate stack structure GST[B] may overlap with the cell array region CAR, the first contact region CTA1, and the second contact region CTA2 of the semiconductor substrate 101. A first end portion of each of the first gate stack structure GST[A] and the second gate stack structure GST[B] may overlap with the first contact region CTA1 in which the first pass transistor PT1 is formed, and may include a first stepped structure formed of first local lines. A second end portion of each of the first gate stack structure GST[A] and the second gate stack structure GST[B] may overlap with the second contact region CTA2 in which the second pass transistor PT2 is formed, and may include a second stepped structure formed of second local lines. In an embodiment, the first local lines may serve as the source select lines SSL among the plurality of conductive patterns 213, and the second local lines may serve as the word lines WL and the drain select lines DSL among the plurality of conductive patterns 213. The source select lines SSL may extend longer on a plane parallel to a top surface of the semiconductor substrate 101 as becoming more distant from the semiconductor substrate 101, thereby forming the first stepped structure SW1. The word lines WL and the drain select lines DSL may extend longer on a plane parallel to the top surface of the semiconductor substrate 101 as becoming more distant from the semiconductor substrate 101, thereby forming the second stepped structure SW2.

The plurality of cell plugs CPL may overlap with the cell array region CAR of the semiconductor substrate 101. Each cell plug CPL may include a memory layer 215, a channel layer 217, and a core insulating layer 219.

The channel layer 217 may penetrate the plurality of interlayer insulating layers 211 and the plurality of conductive patterns 213 of each of the first gate stack structure GST[A] and the second gate stack structure GST[B]. The memory layer 215 may be disposed between the channel layer 217 and each of the first gate stack structure GST[A] and the second gate stack structure GST[B], and surround a sidewall of the channel layer 217.

Although not shown in the drawings, the memory layer 215 may include a blocking insulating layer, a data storage layer, and a tunnel insulating layer. The blocking insulating layer may be disposed between each conductive pattern 213 and the channel layer 217, the data storage layer may be disposed between the blocking insulating layer and the channel layer 217, and the tunnel insulating layer may be disposed between the data storage layer and the channel layer 217. The data storage layer may be formed of a material layer capable of storing data changed using Fowler-Nordheim tunneling. The material layer may include a nitride layer in which charges can be trapped. The tunnel insulating layer may include an insulating material through which charges can tunnel.

The channel layer 217 may be in contact with a source layer 311S. The source layer 311S may constitute the common source line CSL described with reference to FIG. 2A. The source layer 311S may extend to overlap the first gate stack structure GST[A] and the second gate stack structure GST[B]. The first gate stack structure GST[A] and the second gate stack structure GST[B] may be disposed between the source layer 311S and the semiconductor substrate 101. The source layer 311S may be formed of a doped semiconductor layer. In an embodiment, the source layer 311S may be n-type doped silicon.

The channel layer 217 may be formed of a semiconductor layer including silicon. The channel layer 217 may include a first part P1 protruding farther in the third direction D3 toward the source layer 311S than each of the first gate stack structure GST[A], the second gate stack structure GST[B], and the memory layer 215. The first part P1 may be surrounded by the source layer 311S, and be in direct contact with the source layer 311S. The channel layer 217 may include a second part P2 extending toward the semiconductor substrate 101 from the first part P1. The second part P2 may be formed in a tube shape. The tube-shaped second part P2 may surround a sidewall of the core insulating layer 219. The core insulating layer 219 may protrude farther in the third direction D3 than the memory layer 215, and be surrounded by the first part P1 of the channel layer 217. The channel layer 217 may include a third part P3 extending toward the semiconductor substrate 101 from the second part P2. The third part P3 of the channel layer 217 may be doped with a conductivity type impurity. In an embodiment, the third part P3 of the channel layer 217 may be doped with an n-type impurity. The third part P3 of the channel layer 217 may include an overlap region surrounded by a portion of each of the first gate stack structure GST[A] and the second gate stack structure GST[B], and a protrusion region protruding farther toward the semiconductor substrate 101 than each of the first gate stack structure GST[A] and the second gate stack structure GST[B]. The overlap region of the third part P3 may be designed to have various lengths in the third direction D3 according to a design rule. The third part P3 of the channel layer 217 may extend along a surface of the core insulating layer 219, which faces the semiconductor substrate 101.

Memory cells may be formed at intersection portions of the channel layer 217 and the word lines WL, source select transistors may be formed at intersection portions of the channel layer 217 and the source select lines SSL, and drain select transistors may be formed at intersection portions of the channel layer 217 and the drain select lines DSL. The source select transistors, the drain select transistors, and the memory cells are connected in series by the channel layer 217, to constitute the memory cell string CS described with reference to FIG. 2.

The semiconductor memory device may further include a filling insulating layer 221 disposed between the semiconductor substrate 101 and the memory cell array including the first gate stack structure GST[A] and the second gate stack structure GST[B]. The filling insulating layer 221 may fill a groove defined due to the first stepped structure SW1 and the second stepped structure SW2 of each of the first gate stack structure GST[A] and the second gate stack structure GST[B]. The filling insulating layer 221 may surround an end portion of the cell plug CPL, which faces the semiconductor substrate 101.

The semiconductor memory device may include a first gate vertical contact 223A overlapping with the first stepped structure SW1 and a second gate vertical contact 2238 overlapping with the second stepped structure SW2. Each of the first local lines of the first stepped structure SW1 may be in contact with a first gate vertical contact 223A corresponding thereto, and each of the second local lines of the second stepped structure SW2 may be in contact with a second gate vertical contact 2238 corresponding thereto. For example, the source select line SSL constituting the first local line may be in contact with the first gate vertical contact 223A, and the drain select line DSL constituting the second local line may be in contact with the second gate vertical contact 2238. The first gate vertical contact 223A and the second gate vertical contact 2238 may penetrate the filling insulating layer 221 and the interlayer insulating layers 211.

The filling insulating layer 221 may extend to overlap with the row decoder region RDA. A portion of the filling insulating layer 221 overlapping with the row decoder region RDA may be penetrated by a peripheral vertical contact 223C.

The first gate vertical contact 223A, the second gate vertical contact 2238, and the peripheral vertical contact 223C may be formed of the same conductive material.

The filling insulating layer 221 may be penetrated by the slit SI. The slit SI may be disposed between the first gate stack structure GST[A] and the second gate stack structure GST[B], and extend in the first direction D1. The slit SI may be filled with a vertical insulating layer 231 and a vertical conductive line 233. The vertical insulating layer 231 and the vertical conductive line 233 may extend to the inside of the source layer 311S.

The vertical conductive line 233 may constitute a block word line BLKWL commonly connected to gate electrodes of a plurality of first pass transistors PT1 and a plurality of pass transistors PT2 as shown in FIG. 2A. The vertical conductive line 233 may extend in the first direction D1 to overlap with the row decoder region RDA, the first overlap region OLA1, the second overlap region OLA2, and the third overlap region OLA3.

The source layer 311S may extend to overlap with not only the first gate stack structure GST[A] and the second gate stack structure GST[B] but also the vertical conductive line 233. The vertical conductive line 233 may be insulated from the plurality of conductive patterns 213 and the source layer 311S by the vertical insulating layer 231. The vertical insulating layer 231 may extend along a sidewall of the vertical conductive line 233, and extend between the vertical conductive line 233 and the source layer 311S. In other words, the vertical insulating layer 231 may extend along surfaces of the vertical conductive line 233, which face the first gate stack structure GST[A], the second gate stack structure GST[B], and the source layer 311S.

The vertical conductive lien 233 and the vertical insulating layer 231 may protrude farther toward the source layer 311S than the memory layer 215. The vertical insulating layer 231 may be formed to have a thickness thicker than that of the memory layer 215. Accordingly, the vertical conductive line 233 may be protected by the vertical insulating layer 231 during a process of removing a portion of the memory layer 215 to expose the first part P1 of the channel layer 217.

A plurality of insulating layers may be disposed between the semiconductor substrate 101 and the filling insulating layer 221. For example, a peripheral-circuit-side insulating structure 131, a first insulating structure 251, a second insulating structure 261, a third insulating structure 271, and a fourth insulating structure 281 may be disposed between the semiconductor substrate 101 and the filling insulating layer 221.

The peripheral-circuit-side insulating structure 131 may extend to cover the semiconductor substrate 101, the first pass transistor PT1, the second pass transistor PT2, the first transistor TR1, and the second transistor TR2. The peripheral-circuit-side insulating structure 131 may include two or more insulating layers. A plurality of first interconnections 110 and a plurality of first conductive bonding pattern 121 may be buried in the peripheral-circuit-side insulating structure 131.

Each first interconnection 110 may include two or more conductive patterns stacked in the third direction D3. In an embodiment, each first interconnection 110 may include a first conductive pattern 111 connected to the junction 101J or the gate electrode 107, a second conductive pattern 113 on the first conductive pattern 111, a third conductive pattern 115 on the second conductive pattern 113, and a fourth conductive pattern 117 on the third conductive pattern 115. Hereinafter, the present disclosure is described based on an embodiment in which the first interconnection 110 includes a stacked structure of the first conductive pattern 111, the second conductive pattern 113, the third conductive pattern 115, and the fourth conductive pattern 117. However, the present disclosure is not limited thereto.

The plurality of first interconnections 110 may include conductive patterns individually connected to the first pass transistor PT1, the second pass transistor PT2, the first transistor TR1, and the second transistor TR2. For example, some of a plurality of fourth conductive pattern 117 may serve as a first lower conductive line 117L1, a second lower conductive line 117L2, a third lower conductive line 117L3, and a fourth lower conductive line 117L4.

The first lower conductive line 117L1 may be connected to the gate electrode 107 of the first pass transistor PT1. The first lower conductive line 117L1 may be disposed between the first pass transistor PT1 and a gate stack structure (e.g., GST[A]) corresponding thereto. The first lower conductive line 117L1 may be connected to the first pass transistor PT1. The first lower conductive line 177L1 may overlap with the first contact region CTA1. The first lower conductive layer 117L1 may extend between the vertical conductive line 233 and the first overlap region OLA1 of the semiconductor substrate 101. Accordingly, the first lower conductive line 117L1 may overlap with the vertical conductive line 233. The first local line among the plurality of conductive patterns 213 may be connected to the first pass transistor PT1 via at least one conductive pattern connected to the junction 101J of the first pass transistor PT1 among the fourth conductive patterns 117. The first local line may be the first conductive pattern among the plurality of conductive patterns 213. In an embodiment the first local line may be the source select line SSL.

The second lower conductive line 117L2 may be connected to the gate electrode 107 of the second pass transistor PT2. The second lower conductive line 117L2 may be disposed between the second pass transistor PT2 and a gate stack structure (e.g., GST[A]) corresponding thereto. The second lower conductive line 117L2 may overlap with the second contact region CTA2. The second lower conductive line 117L2 may extend between the vertical conductive line 233 and the second overlap region OLA2 of the semiconductor substrate 101. Accordingly, the second lower conductive line 117L2 may overlap with the vertical conductive line 233. The second local line among the plurality of conductive patterns 213 may be connected to the second pass transistor PT2 via at least one conductive pattern connected to the junction 101J of the second pass transistor PT2 among the fourth conductive patterns 117. The second local line may be the second conductive pattern among the plurality of the conductive patterns 213. In an embodiment, the second local line may be the word line WL.

The third lower conductive line 117L3 may be connected to the second transistor TR2 of the row decoder. The third lower conductive line 117L3 may be disposed at a level between the first pass transistor PT1 and the first gate stack structure GST[A]. In an embodiment, the third lower conductive line 117L3 may be substantially disposed at the same level as the first lower conductive line 117L1 and the second lower conductive line 117L2. The third lower conductive line 117L3 may be disposed between the row decoder region RDA of the semiconductor substrate 101 and the vertical conductive line 233. Accordingly, the third lower conductive line 117L3 may overlap with the vertical conductive line 233. The second transistor TR2 may be connected to the vertical conductive line 233 via the third lower conductive line 117L3. The third lower conductive line 117L3 may be connected to a junction 101J corresponding to a block select signal output terminal of the second transistor TR2.

The fourth conductive line 117L4 may be connected to the first transistor TR1 of the page buffer. The fourth lower conductive line 117L4 may be disposed at a level between the first pass transistor PT1 and the first gate stack structure GST[A]. In an embodiment, the fourth lower conductive line 117L4 may be substantially disposed at the same level as the first lower conductive line 117L1 and the second lower conductive line 117L2. The first transistor TR1 may be connected to the channel layer 217 via the fourth lower conductive line 117L4.

The plurality of first conductive bonding patterns 121 may be disposed at a level between the plurality of first interconnections 110 and the memory cell array. The plurality of first conductive bonding patterns 121 may be connected to the first pass transistor PT1, the second pass transistor PT2, the first transistor TR1, and the second transistor TR2, which constitute the peripheral circuit structure, via the plurality of first interconnections 110.

The first insulating structure 251, the second insulating structure 261, the third insulating structure 271, and the fourth insulating structure 281 may be disposed at a level between the plurality of first conductive bonding patterns 121 and the memory cell array.

The first insulating structure 251 may be in contact with the filling insulating layer 221 to extend in parallel to the semiconductor substrate 101. The first insulating structure 251 may include at least one insulating layer. The first insulating structure 251 may be penetrated by a plurality of fifth conductive patterns 255A to 255G. The plurality of fifth conductive patterns 255A to 255G may include a fifth conductive pattern 255A in contact with the first gate vertical contact 223A, a fifth conductive pattern in contact with the second gate vertical contact 2238, a fifth conductive pattern 255C in contact with the channel layer 217 of the cell plug CPL, a fifth conductive pattern 255D in contact with a portion of the vertical conductive line 233, which overlaps with the first overlap region OLA1, a fifth conductive pattern 255E in contact with a portion of the vertical conductive line 233, which overlap with the second overlap region OLA2, a fifth conductive pattern 255F in contact with a portion of the vertical conductive line 233, which overlaps with the row decoder region RDA, and a fifth conductive pattern 255G in contact with the peripheral vertical contact 223C. The fifth conductive pattern 255C may penetrate the filling insulating layer 221 between the first insulating structure 251 and the channel layer 217.

The second insulating structure 261 may be in contact with the first insulating structure 251 to extend in parallel to the semiconductor substrate 101. A plurality of sixth conductive patterns 263A to 263G and a plurality of seventh conductive patterns 265A to 265G may be buried in the second insulating structure 261. The second insulating structure 261 may include at least one insulating layer. In an embodiment, the second insulating structure 261 may include a first insulating layer penetrated by the plurality of sixth conductive patterns 263A to 263G and a second insulating layer penetrated by the plurality of seventh conductive patterns 265A to 265G.

The plurality of sixth conductive patterns 263A to 263G may include a sixth conductive pattern 263A connected to the first gate vertical contact 223A via the fifth conductive pattern 255A, a sixth conductive pattern 263B connected to the second gate vertical contact 223B via the fifth conductive pattern 255B, a sixth conductive pattern 263C connected to the channel layer 217 via the fifth conductive pattern 255C, a sixth conductive pattern 263D connected to the vertical conductive line 233 via the fifth conductive pattern 255D, a sixth conductive pattern 263E connected to the vertical conductive line 233 via the fifth conductive pattern 255E, a sixth conductive pattern 263F connected to the vertical conductive line 233 via the fifth conductive pattern 255F, and a sixth conductive pattern 263F connected to the peripheral vertical contact 223C via the fifth conductive pattern 255G.

The plurality of seventh conductive patterns 265A to 265G may include a seventh conductive pattern 265A connected to the fifth conductive pattern 255A via the sixth conductive pattern 263A, a seventh conductive pattern 265B connected to the fifth conductive pattern 255B via the sixth conductive pattern 263B, a seventh conductive pattern 265C connected to the fifth conductive pattern 255C via the sixth conductive pattern 263C, a seventh conductive pattern 265D connected to the fifth conductive pattern 255D via the sixth conductive pattern 263D, a seventh conductive pattern 265E connected to the fifth conductive pattern 255E via the sixth conductive pattern 263E, a seventh conductive pattern 265F connected to the fifth conductive pattern 255F via the sixth conductive pattern 263F, and a seventh conductive pattern 265G connected to the fifth conductive pattern 255G via the sixth conductive pattern 263G.

The fifth conductive pattern 255A, the sixth conductive pattern 263A, and the seventh conductive pattern 265A, which are connected to the first gate vertical contact 223A, may constitute a first conductive contact structure CT1. The fifth conductive pattern 255B, the sixth conductive pattern 263B, and the seventh conductive pattern 265B, which are connected to the second gate vertical contact 223B, may constitute a second conductive contact structure CT2. The fifth conductive pattern 255C, the sixth conductive pattern 263C, and the seventh conductive pattern 265C, which are connected to the channel layer 217, may constitute a bit line contact BCC. The fifth conductive pattern 255D, the sixth conductive pattern 263D, and the seventh conductive pattern 265D, which are connected to the vertical conductive line 233 and overlap with the first overlap region OLA1, may constitute a third conductive contact structure CT3. The fifth conductive pattern 255E, the sixth conductive pattern 263E, and the seventh conductive pattern 265E, which are connected to the vertical conductive line 233 and overlap with the second overlap region OLA2, may constitute a fourth conductive contact structure CT4. The fifth conductive pattern 255F, the sixth conductive pattern 263F, and the seventh conductive pattern 265F, which are connected to the vertical conductive line 233 and overlap with the row decoder region RDA, may constitute a fifth conductive contact structure CT5. The fifth conductive pattern 255G, the sixth conductive pattern 263G, and the seventh conductive pattern 265G, which are connected to the peripheral vertical contact 223C, may constitute a sixth conductive contact structure CT6. Hereinafter, an embodiment of the present disclosure is described based on the first to sixth conductive contact structures CT1 to CT6 and the bit line contact BCC, which are configured as described above, but the present disclosure is not limited thereto. The first to sixth conductive contact structures CT1 to CT6 and the bit line contact BCC, which are described above, may be disposed between a level at which the vertical conductive line 233 is disposed and a level at which the first to fourth lower conductive lines 117L1 to 117L4 are disposed.

The third insulating structure 271 may be in contact with the second insulating structure 261 to extend in parallel to the semiconductor substrate 101. The third insulating structure 271 may be penetrated by a plurality of eighth conductive patterns 275A to 275G. The plurality of eighth conductive patterns 275A to 275G may include an eighth conductive pattern 275A connected to the first gate vertical contact 223A via the first conductive contact structure CT1, an eighth conductive pattern 275B connected to the second gate vertical contact 223B via the second conductive contact structure CT2, an eighth conductive pattern 275C connected to the channel layer 217 via the bit line contact BCC, an eight conductive pattern 275D connected to the vertical conductive line 233 via the third conductive contact structure CT3, an eight conductive pattern 275E connected to the vertical conductive line 233 via the fourth conductive contact structure CT4, an eighth conductive pattern 275F connected to the vertical conductive line 233 via the fifth conductive contact structure CT5, and an eighth conductive pattern 275G connected to the peripheral vertical contact 223C via the sixth conductive contact structure CT6. The eighth conductive pattern 275C may constitute a bit line BL. The bit line BL may extend in a direction intersecting the vertical conductive line 223. In an embodiment, the bit line BL may extend in the second direction D2. The bit line BL may be insulated from the vertical conductive line 233 by the first insulating structure 251 and the second insulating structure 261.

The fourth insulating structure 281 may be disposed between the third insulating structure 271 and the peripheral-circuit-side insulating structure 131. The fourth insulating structure 281 may include two or more insulating layers. A plurality of second interconnections 280 and a plurality of second conductive bonding patterns 291 may be buried in the fourth insulating structure 281.

Each second interconnection 280 may include two or more conductive patterns stacked in the third direction D3. In an embodiment, each second interconnection 280 may include a ninth conductive pattern 283 connected to each of the plurality of eighth conductive patterns 275A to 275G, a tenth conductive pattern 285 between the ninth conductive pattern 283 and the first conductive bonding pattern 121, and an eleventh conductive pattern 287 between the tenth conductive pattern 285 and the first conductive bonding pattern 121. Hereinafter, the present disclosure is described based on an embodiment in which the second interconnection 280 includes a stacked structure of the ninth conductive pattern 283, the tenth conductive pattern 285, and the eleventh conductive pattern 287. However, the present disclosure is not limited thereto.

The plurality of second interconnections 280 may be connected to the first gate vertical contact 233A, the second gate vertical contact 233B, the vertical conductive line 233, the peripheral vertical contact 223C, and the channel layer 217 via the first to sixth conductive contact structures CT1 to CT6 and the bit line contact BCC.

The plurality of second conductive bonding patterns 291 may be disposed between the plurality of first conductive bonding patterns 121 and the plurality of second interconnections 280. The plurality of second conductive bonding patterns 291 may be bonded to the plurality of first conductive bonding patterns 121. The plurality of second conductive bonding patterns 291 may be connected to the first gate vertical contact 233A, the second gate vertical contact 2338, the vertical conductive line 233, the peripheral vertical contact 223C, and the channel layer 217 via the plurality of second interconnections 280.

According to the above-described structure, the gate electrode 107 of the first pass transistor PT1 and the gate electrode 107 of the second pass transistor PT2 may be commonly connected to the vertical conductive line 233 via the first lower conductive line 117L1, the second lower conductive line 117L2, the third conductive contact structure CT3, and the fourth conductive contact structure CT4. In addition, the vertical conductive line 233 may be connected to the second lower conductive line 117L3 transmitting a block select signal via the fifth conductive contact CT5.

The semiconductor memory device may include an upper insulating layer 313, an upper contact 315CT, a source contact 315S, a plurality of upper conductive lines 321UL1, 321UL2, and 321UL3, and an upper source line 321S. The upper insulating layer 313 may extend to cover the source layer 311S, the vertical insulating layer 231, and the filling insulating layer 221. The upper contact 315CT may penetrate the upper insulating layer 313 to be in contact with the peripheral vertical contact 223C. The source contact 315S may penetrate the upper insulating layer 313 to be in contact with the source layer 311S. The plurality of upper conductive lines 321UL1, 321UL2, and 321UL3 may transmit signals for an operation of the semiconductor memory device.

For example, an upper conductive line (e.g., 321UL3) transmitting a block select signal among the plurality of upper conductive lines 321UL1, 321UL2, and 321UL3 may be connected to the second transistor TR2 of the row decoder via the upper contact 315CT, the peripheral vertical contact 233C, and the sixth conductive contact structure CT6. The upper conductive line 321UL3 may be connected to a junction corresponding to a black select signal input terminal of the second transistor TR2. The upper source line 321S may be connected to the source layer 311S via the source contact 315S. A source voltage for the operation of the semiconductor memory device may be supplied to the source layer 311S through the source line 321S.

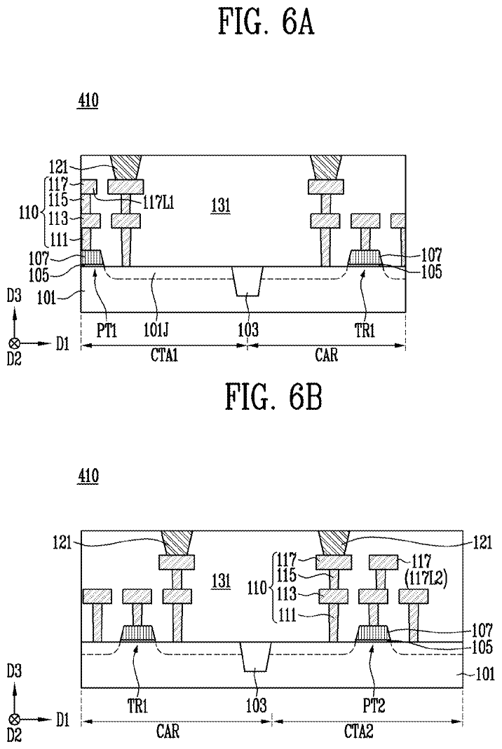

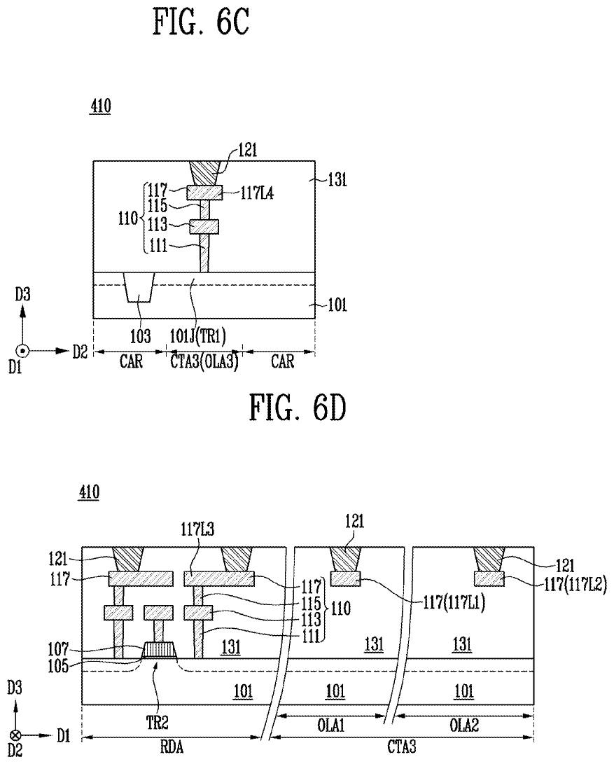

FIGS. 6A, 6B, 6C, 6D, 7A, 7B, 7C, 7D, 8A, 8B, 9A, 9B, 9C, 9D, 10A, 10B, 10C, 10D, 11A, 11B, 11C, 11D, 12A, 12B, 12C, and 12D are process sectional views illustrating an embodiment of a manufacturing method of the semiconductor memory device shown in FIGS. 5A, 5B, 5C, and 5D. Hereinafter, overlapping descriptions of components identical to those shown in FIGS. 5A, 5B, 5C, and 5D will be omitted.

FIGS. 6A to 6D are sectional views illustrating a process of forming a first circuit structure.

Referring to FIGS. 6A to 6D, the process of forming a first circuit structure 410 may include a process of forming a peripheral circuit structure including a first pass transistor PT1, a second pass transistor PT2, a first transistor TR1, and a second transistor TR2. The first pass transistor PT1, the second pass transistor PT2, the first transistor TR1, and the second transistor TR2 may be insulated from each other by isolation layer 103 formed in a semiconductor substrate 101.

The first pass transistor PT1, the second pass transistor PT2, the first transistor TR1, and the second transistor TR2 may be formed in active regions defined in a first contact region CTA1, a cell array region

CAR, a second contact region CTA2, a third contact region CTA3, and a row decoder region RDA of the semiconductor substrate 101. A gate electrode 107 of each of the first pass transistor PT1, the second pass transistor PT2, the first transistor TR1, and the second transistor TR2 may be formed on a gate insulating layer 105 disposed on an active region corresponding thereto. Junctions 101J of each of the first pass transistor PT1, the second pass transistor PT2, the first transistor TR1, and the second transistor TR2 may be formed in active regions at both sides of the gate electrode 107.

The third contact CTA3 of the semiconductor substrate 101 may include a first overlap region OLA1, a second overlap region OLA2, and a third overlap region OLA3 as described with reference to FIGS. 5A to 5D.

The process of forming the first circuit structure 410 may include a process of forming a plurality of first interconnections 110 and a plurality of first conductive bonding patterns 121, which are buried in a peripheral-circuit-side insulating structure 131. The plurality of first interconnections 110 may include a plurality of first conductive patterns 111, a plurality of second conductive patterns 113, a plurality of third conductive patterns 115, and a plurality of fourth conductive patterns 117 as described with reference to FIGS. 5A to 5D. The plurality of fourth conductive patterns 117 may include a first lower conductive line 117L1, a second lower conductive line 117L2, a third lower conductive line 117L3, and a fourth lower conductive line 117L4 as described with reference to FIGS. 5A to 5D.

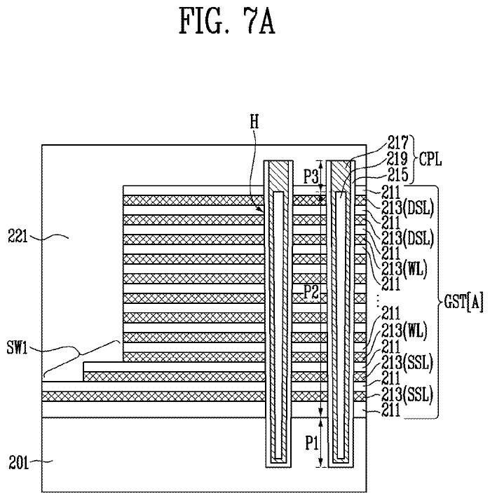

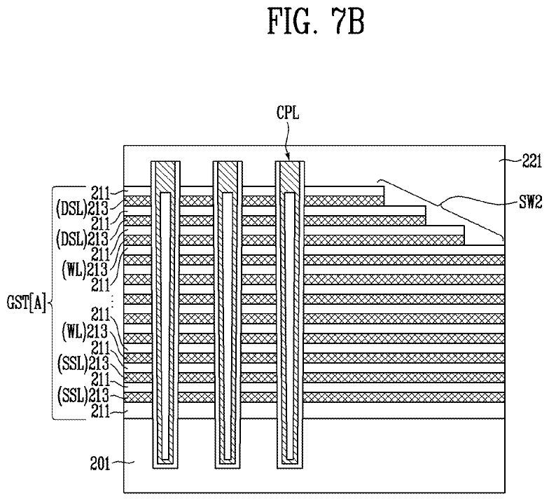

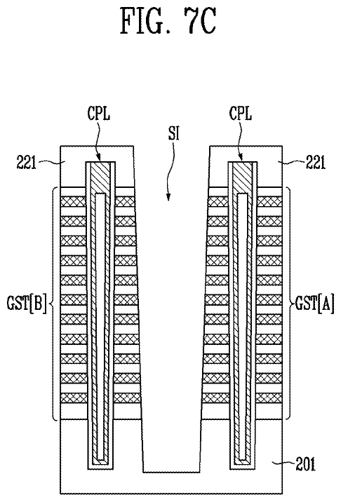

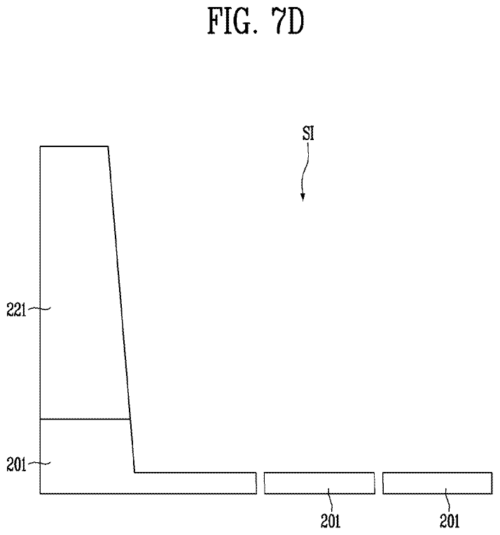

FIGS. 7A to 7D are sectional views illustrating a step of forming a memory cell array.

Referring to FIGS. 7A to 7D, a memory cell array may be formed over the sacrificial substrate 210. The process of forming the memory cell array may include a process of alternately stacking a plurality of first material layers and a plurality of second material layers over the sacrificial substrate 210, a process of forming a hole H which penetrates the plurality of first material layers and the plurality of second material layers and extends to the inside of the sacrificial substrate 210 through an etching process using a mask pattern as an etching barrier, a process of forming a cell plug CPL in the hole H, a process of etching the plurality of first material layers and the plurality of second material layers to define a first stepped structure SW1 and a second stepped structure SW2, a process of removing the mask pattern, a process of forming a filling insulating layer 221 over the sacrificial substrate 210, and a process of forming a slit SI which penetrates the filling insulating layer 221, the plurality of first material layers, and the plurality of second material layers and extends to the inside of the sacrificial substrate 201. The first material layer and the second material layer may be formed of various materials. In an embodiment, the first material layer may be formed of the same insulating material as a plurality of interlayer insulating layer 211, and the second material layer may be formed of a sacrificial material having an etching selectivity with respect to the insulating material. Hereinafter, the present disclosure is described based on an embodiment in which the first material layer is formed of an insulating material and the second material layer is formed of a sacrificial material. However, the present disclosure is not limited thereto.

The process of forming the memory cell array may further include a process of selectively removing the second material layers formed of the sacrificial material and a process of respectively filling regions in which the second material layers are removed with a plurality of conductive pattern 213.

Through the above-described process, a first gate stack structure GST[A] and a second gate stack structure GST[B] of the memory cell array may be formed. Each of the first gate stack structure GST[A] and the second gate stack structure GST[B] may surround the cell plug CPL, and include the plurality of interlayer insulating layers 211 and a plurality of conductive patterns 213, which are alternately stacked over the sacrificial substrate 201. The plurality of conductive patterns 213 may constitute the first stepped structure SW1 and the second stepped structure SW2. In an embodiment, source select lines SSL constituting first local lines among the plurality of conductive patterns 213 may constitute the first stepped structure SW1, and word lines WL and drain select lines DSL, which constitute second local lines, among the plurality of conductive patterns 213 may constitute the second stepped structure SW2.

The process of forming the cell plug CPL may include a process of forming a memory layer 215, a process of forming a liner semiconductor layer on the memory layer 215, a process of filling a portion of a central region of the hole H, which is opened by the liner semiconductor layer, with a core insulating layer 219, and a process of filling the other portion of the central region of the hole H with a doped semiconductor layer. The doped semiconductor layer and the liner semiconductor layer may constitute a channel layer 217. Because the memory layer 215 extends along a sidewall and a bottom surface of the hole H, the memory layer 215 may be disposed between the sacrificial substrate 201 and the channel layer 217. The channel layer 217 may include a first part P1 extending to a level of the sacrificial substrate 201, a second part P2 extending from the first part P1, and a third part P3 extending onto the core insulating layer 219 from the second part P2. The third part P3 may include a conductivity type impurity. In an embodiment, the third part P3 may include an n-type impurity.

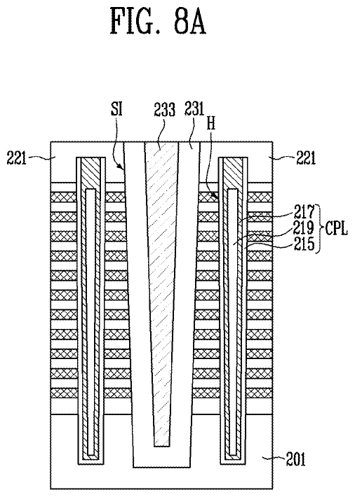

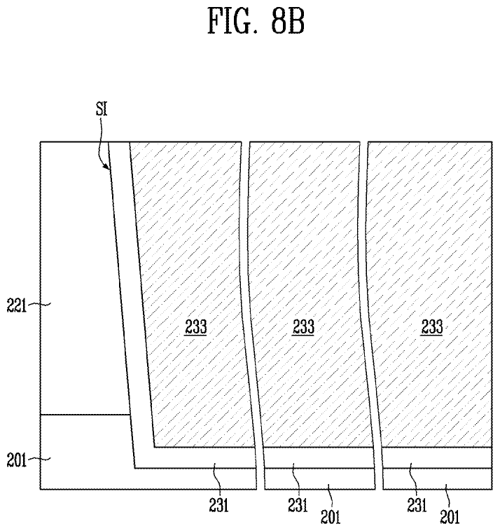

FIGS. 8A and 8B are sectional views illustrating a process of forming a vertical insulating layer 231 and a vertical conductive line 233.

Referring to FIGS. 8A and 8B, the vertical insulating layer 231 may be formed along a surface of the slit SI. A thickness of the vertical insulating layer 23 formed on the surface of the slit SI may be controlled greater than that of the memory layer 215 formed on a surface of the hole H .

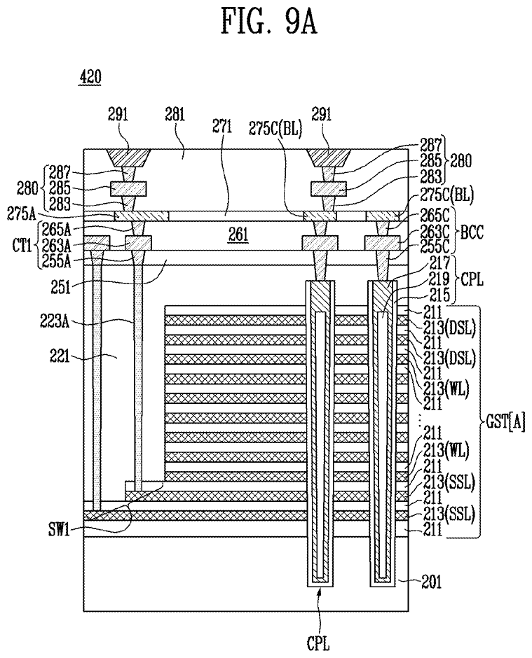

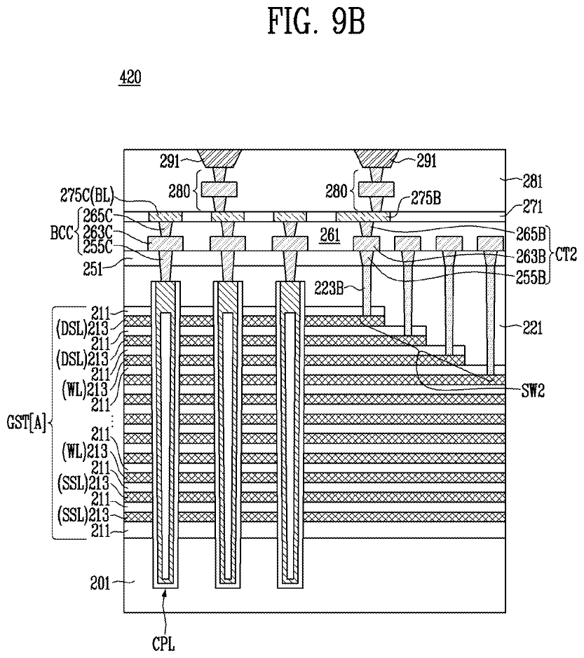

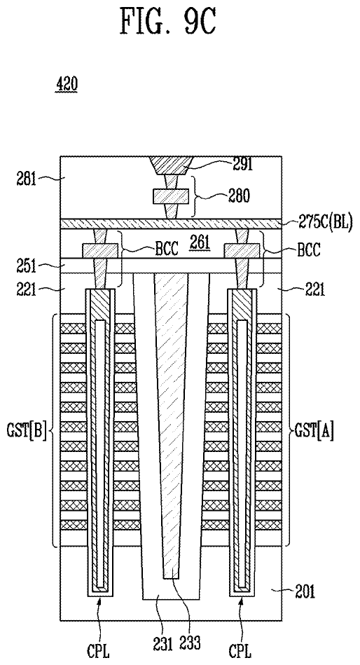

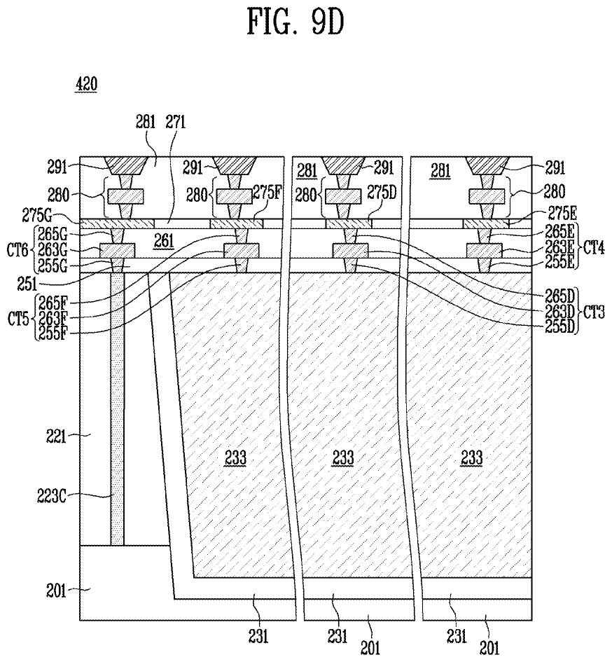

FIGS. 9A to 9D are sectional views illustrating example subsequent processes continued after the vertical conductive line 233 is formed.

Referring to FIGS. 9A to 9D, a first gate vertical contact 223A, a second gate vertical contact 223B, and a peripheral vertical contact 223C may be formed, which penetrate the filling insulating layer 221.

Each of the first gate vertical contact 223A and the second gate vertical contact 223B may penetrate the interlayer insulating layer 211 to be in contact with the conductive pattern 213. For example, the first gate vertical contact 223A may be in contact with the source select line SSL constituting the first stepped structure SW1, and the second gate vertical contact 223B may be in contact with the drain select line DSL constituting the second stepped structure SW2.

The peripheral vertical contact 223C may be in contact with the sacrificial substrate 201 not overlapping with the first gate stack structure GST[A], the second gate stack structure GST[B], the vertical insulating layer 231, and the vertical conductive line 223.

Subsequently, a first insulating structure 251 may be formed on the filling insulating layer 221. The first insulating structure 251 may extend to cover the first gate vertical contact 223A, the second gate vertical contact 223B, the peripheral vertical contact 223C, the vertical insulating layer 231, and the vertical conductive line 233.

Subsequently, a plurality of fifth conductive patterns 255A to 255G may be formed, which penetrate at least one of the first insulating structure 251 and the filling insulating layer 221. Continuously, a process of forming a plurality of sixth conductive patterns 263A to 263G and a process of a plurality of seventh conductive patterns 265A to 265G may be sequentially performed. The second insulating structure 261 may include an insulating layer penetrated by the plurality of sixth conductive patterns 263A to 263G and an insulating layer penetrated by the plurality of seventh conductive patterns 265A to 265G. The plurality of fifth conductive patterns 255A to 255G, the plurality of sixth conductive patterns 263A to 263G, and the plurality of seventh conductive patterns 265A to 265G may constitute a first conductive contact structure CT1, a second conductive contact structure CT2, a bit line contact structure BCC, a third conductive contact structure CT3, a fourth conductive contact structure CT4, a fifth conductive contact structure CT5, and a sixth conductive contact structure CT6.

Subsequently, a process of forming a third insulating structure 271 on the second insulating structure 261, a process of forming a plurality of eighth conductive patterns 275A to 275G penetrating the third insulating structure 271, a process of forming a plurality of second interconnections 280 connected to the plurality of eighth conductive patterns 275A to 275G, and a process of forming a plurality of second conductive bonding patterns 291 connected to the plurality of second interconnections 280 may be sequentially performed.

The process of forming the plurality of second interconnections 280 may include a process of forming a first insulating layer on the third insulating structure 271, a process of forming a plurality of ninth conductive patterns 283 penetrating the first insulating layer, a process of forming a second insulating layer on the first insulating layer, a process of forming a plurality of tenth conductive patterns 285 penetrating the second insulating layer, a process of forming a third insulating layer on the second insulating layer, and a process of forming a plurality of eleventh conductive patterns 287 penetrating the third insulating layer. A process of forming a plurality of second conductive bonding patterns 291 may be performed after a fourth insulating layer is formed on the third insulating layer. The plurality of second conductive bonding patterns 291 may be formed to penetrate the fourth insulating layer. The above-described first to fourth insulating layers may constitute a fourth insulating structure 281.

A second circuit structure 420 may be defined on the sacrificial substrate 201 through the processes described with reference to FIGS. 7A to 7D, 8A and 8B, and 9A to 9D.

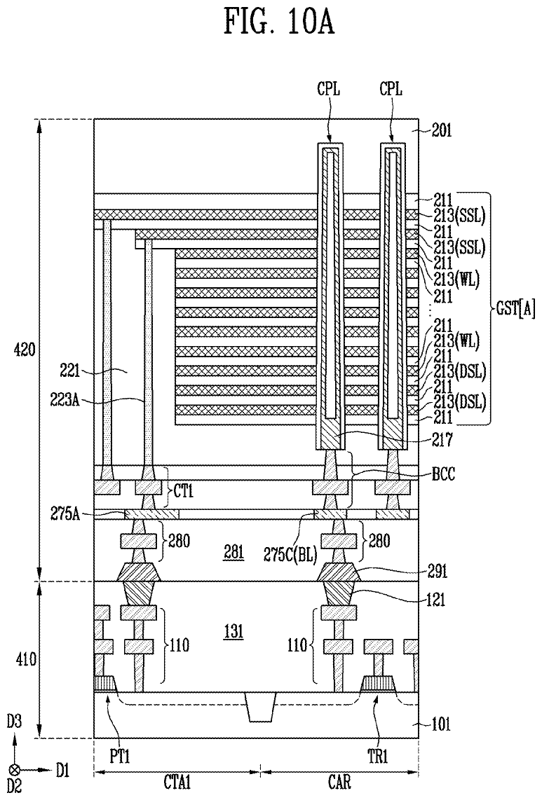

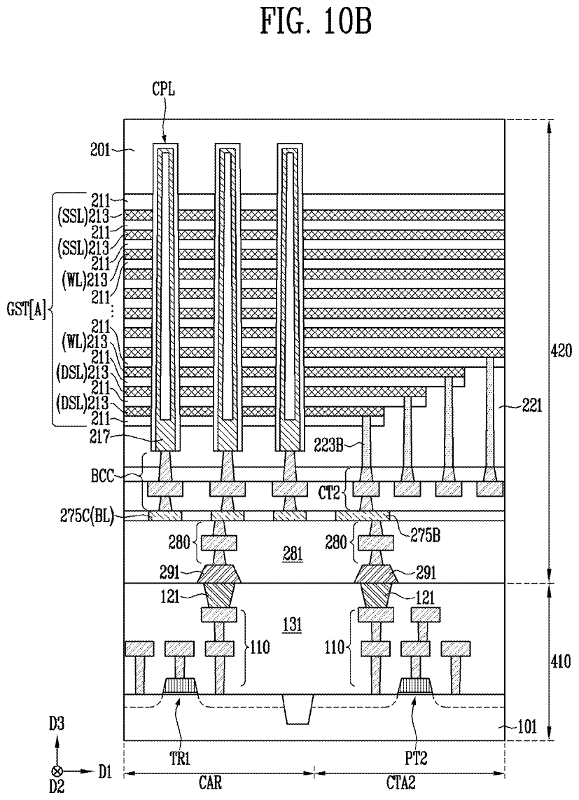

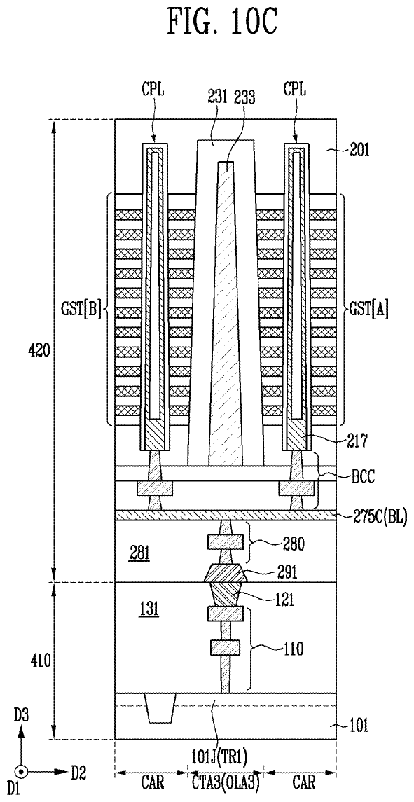

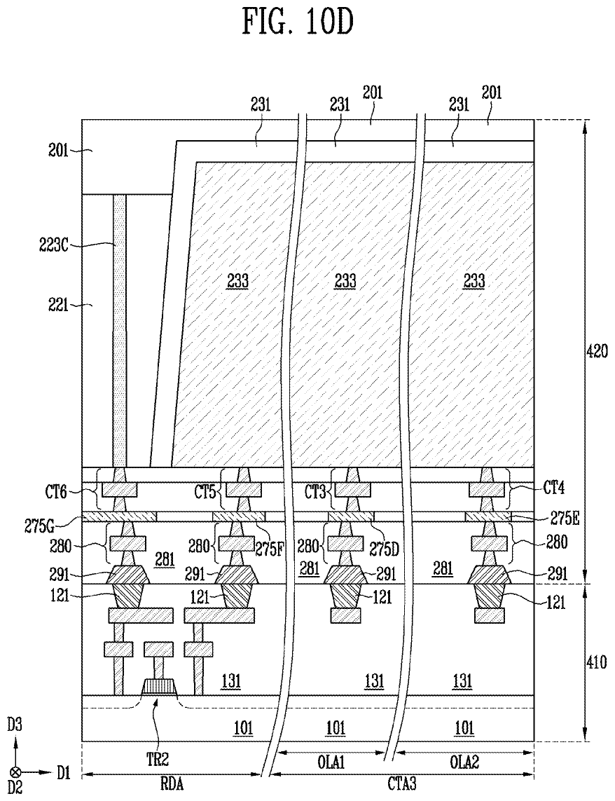

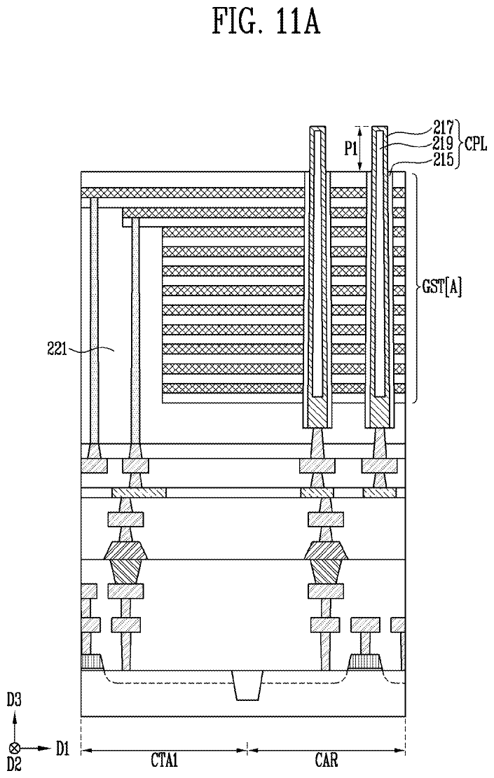

FIGS. 10A and 10D illustrate a process of connecting the first circuit structure 410 and the second circuit structure 420 to each other.

Referring to FIGS. 10A to 10D, the first circuit structure 410 and the second circuit structure 420, which are individually provided, may be connected to each other through a bonding process. The plurality of first conductive bonding patterns 121 of the first circuit structure 410 may be bonded to the plurality of second conductive bonding patterns 291. Accordingly, the plurality of conductive patterns 213, the bit line BL, the vertical conductive line 233, and the peripheral vertical contact 233C of the second circuit structure 420 may be connected to the first pass transistor PT1, the second pass transistor PT2, the first transistor TR1, and the second transistor TR2 of the peripheral circuit structure via the plurality of first interconnections 110, the plurality of first conductive bonding patterns 121, the plurality of second conductive bonding patterns 291, and the plurality of second interconnections 280.

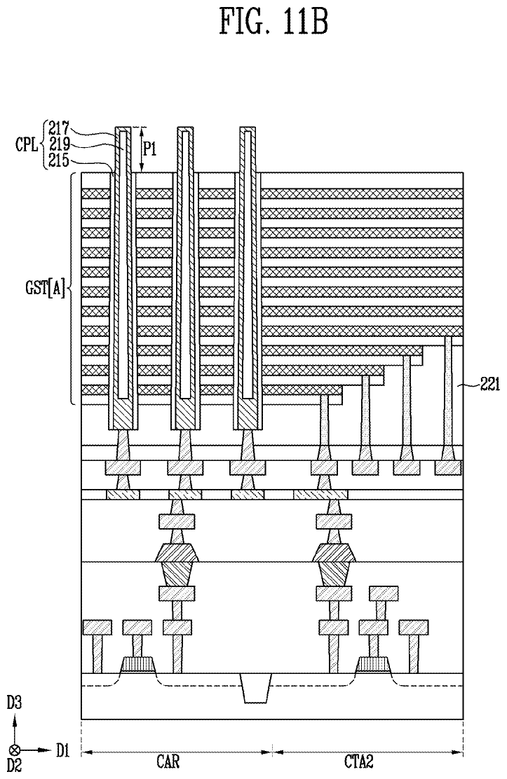

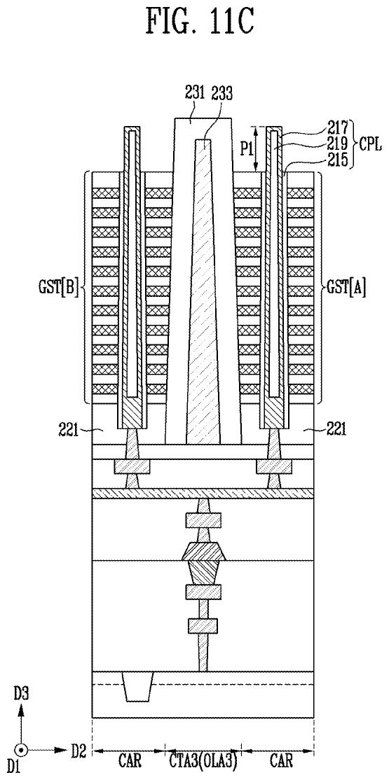

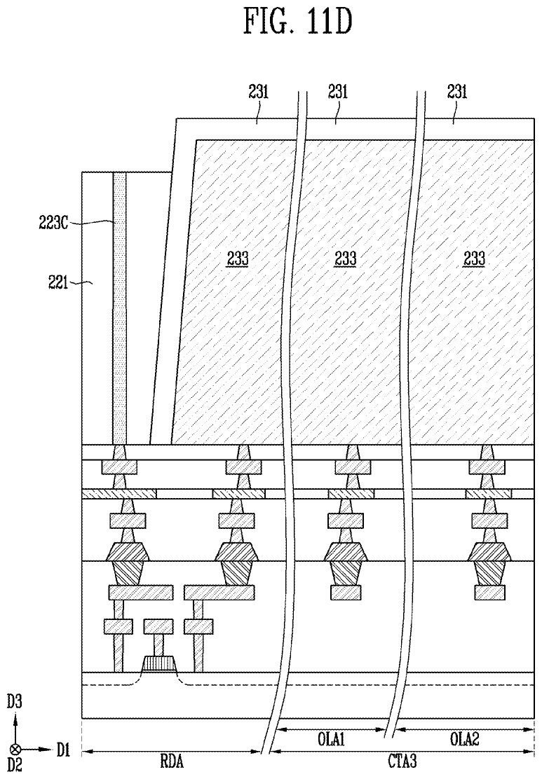

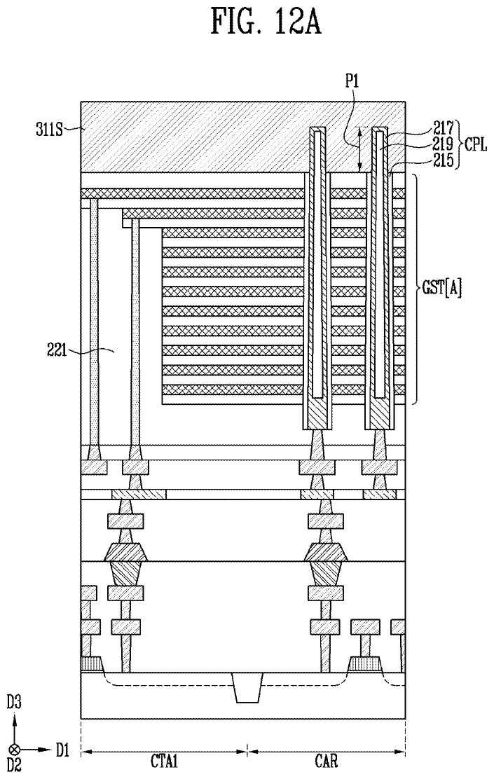

FIGS. 11A to 11D illustrate a process of exposing the first part P1 of the channel layer 217 and the peripheral vertical contact 223C.

Referring to FIGS. 11A to 11D, portions of the peripheral vertical contact 223C and the memory layer 215 may be exposed by removing the sacrificial substrate 201 shown in FIGS. 10A to 10D. A portion of the vertical insulating layer 231 and a portion of the filling insulating layer 221 may be exposed. Therefore, the portion of the memory layer 215 may be removed through an etching process such that the first part P1 of the channel layer 217 may be exposed. While the memory layer 215 is removed, a portion of the vertical insulating layer 231 may be etched. Because the vertical insulating layer 231 is formed thicker than the memory layer 215, the vertical insulating layer 231 may remain to block the vertical conductive line 233.

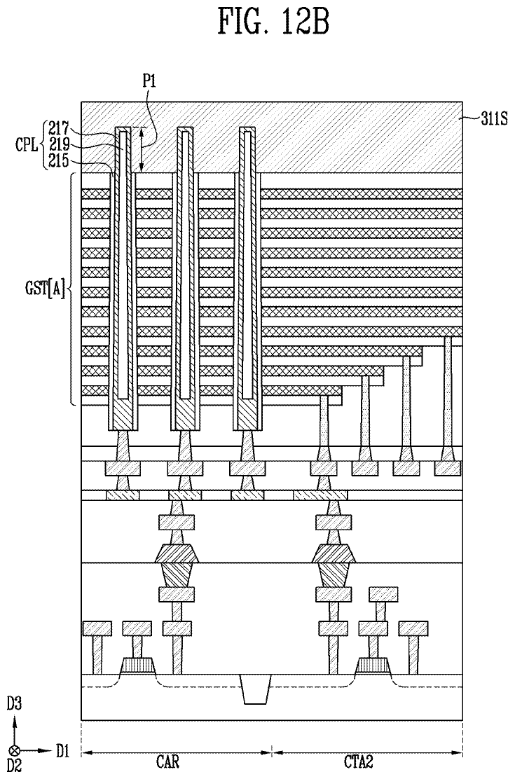

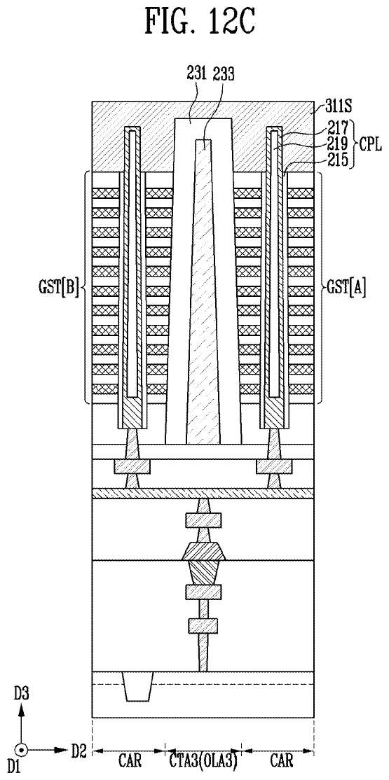

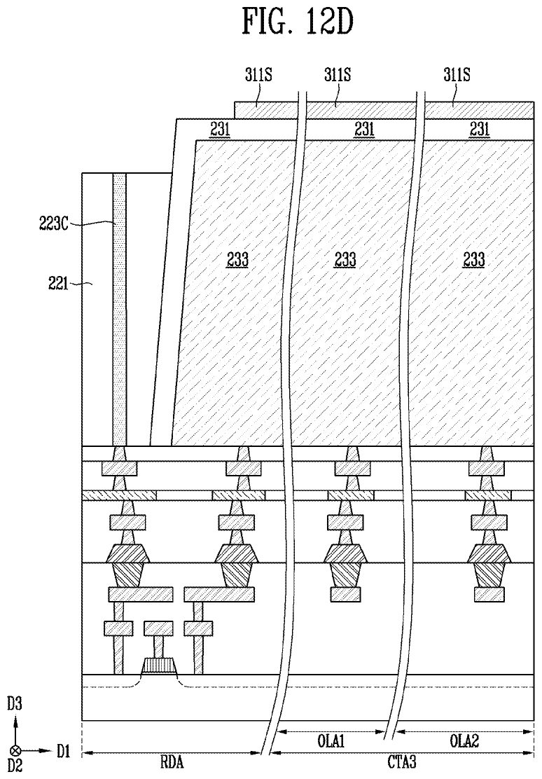

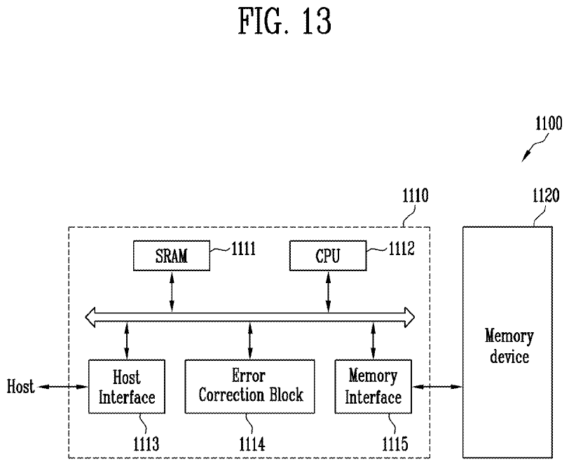

FIGS. 12A to 12D illustrate a process of forming a source layer 311S.

Referring to FIGS. 12A to 12D, the process of forming the source layer 311S may include a step of forming a doped semiconductor layer to cover the first part P1 of the channel layer 217, the vertical insulating layer 231, and the filling insulating layer 221 and a process of defining the source layer 311S by etching the doped semiconductor layer. The doped semiconductor layer may be etched such that the peripheral vertical contact 233C is exposed.

Subsequently, subsequent processes of forming the upper insulating layer 313, the upper contact 315CT, the source contact 315S, the plurality of upper conductive lines 321UL1, 321UL2, and 321UL3, and the upper source line 321S, which are shown in FIGS. 5A to 5D may be performed.

FIG. 13 is a block diagram illustrating a configuration of a memory system in accordance with an embodiment of the present disclosure.

Referring to FIG. 13, the memory system 1100 includes a memory device 1120 and a memory controller 1110.

The memory device 1120 may be a multi-chip package configured with a plurality of flash memory chips. The memory device 1120 may include a memory cell array and a vertical conductive line disposed across the memory cell array. In an embodiment, the vertical conductive line may be disposed between a first gate stack structure and a second gate stack structure of the memory cells array, which are spaced apart from each other. Also, the memory device 1120 may include circuit groups which are commonly connected to the vertical conductive line and are disposed in regions spaced apart from each other.

The memory controller 1110 controls the memory device 1120, and may include Static Random Access Memory (SRAM) 1111, a Central Processing Unit (CPU) 1112, a host interface 1113, an error correction block 1114, and a memory interface 1115. The SRAM 1111 is used as operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120, and corrects the detected error. The memory interface 1115 interfaces with the memory device 1120. The memory controller 1110 may further include Read Only Memory (ROM) for storing code data for interfacing with the host, and the like.

The memory system 1100 configured as described above may be a memory card or a Solid State Drive (SSD), in which the memory device 1120 is combined with the controller 1110. For example, when the memory system 1100 is an SSD, the memory controller 1100 may communicate with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

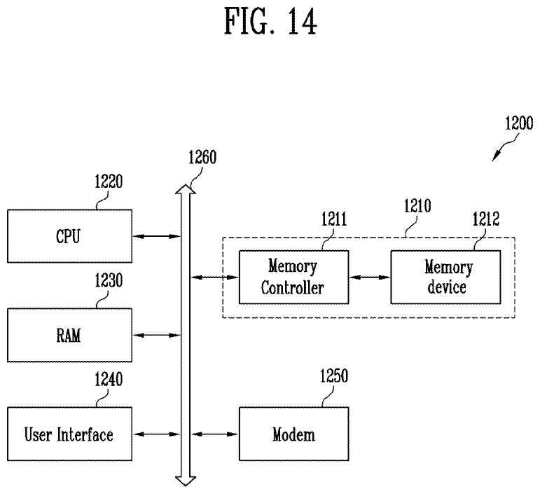

FIG. 14 is a block diagram illustrating a configuration of a computing system in accordance with an embodiment of the present disclosure.

Referring to FIG. 14, the computing system 1200 may include a CPU 1220, random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, mobile D-RAM, and the like may be further included.

The memory system 1210 may be configured with a memory device 1212 and a memory controller 1211.

The memory device 1212 may include a memory cell array and a vertical conductive line disposed across the memory cell array. In an embodiment, the vertical conductive line may be disposed between a first gate stack structure and a second gate stack structure of the memory cells array, which are spaced apart from each other. Also, the memory device 1120 may include circuit groups which are commonly connected to the vertical conductive line and are disposed in regions spaced apart from each other.

The memory controller 1211 may be configured identically to the memory controller 1110 described above with reference to FIG. 13.

In accordance with the present disclosure, circuit groups which constitute a peripheral circuit structure and are spaced apart from each other may be connected to each other through a vertical conductive line disposed in a space between gate stack structures of a memory cell array. Accordingly, the area of a semiconductor substrate occupied by the peripheral circuit structure and lines connected to the peripheral circuit structure may be reduced, and thus the size of the semiconductor memory device may be reduced.

What is claimed is:

1. A semiconductor memory device comprising:
a first gate stack structure and a second gate stack structure, including a first conductive pattern and a second conductive pattern, the first conductive pattern spaced apart from the second conductive pattern, the first gate stack structure adjacent to the second gate stack structure;
a vertical conductive line disposed adjacent to the first gate stack structure and the second gate stack structure; and
a semiconductor substrate extending to overlap with the first gate stack structure, the second gate stack structure, and the vertical conductive line,
wherein the semiconductor substrate includes a plurality of pass transistors connected to the first and second conductive patterns of at least one of the first gate stack structure and the second gate stack structure, and
wherein the vertical conductive line is connected to a plurality of gate electrodes of the plurality of pass transistors.

2. The semiconductor memory device of claim 1, wherein, on a plane parallel to the semiconductor substrate, the vertical conductive line extends in a first direction, and the first gate stack structure and the second gate stack structure are adjacent to each other in a second direction intersecting the vertical conductive line,
wherein the first gate stack structure includes a first end portion and a second end portion spaced apart from the first end portion in the first direction, and
wherein the plurality of pass transistors include a first pass transistor overlapping with the first end portion of the first gate stack structure and a second pass transistor overlapping with the second end portion of the first gate stack structure.

3. The semiconductor memory device of claim 2, wherein the semiconductor substrate includes:
a first contact region in which the first pass transistor is disposed;
a second contact region in which the second pass transistor is disposed;
a cell array region between the first contact region and the second contact region;
a third contact region overlapping with the vertical conductive line; and
a row decoder region facing the second contact region with the first contact region and the cell array region, which are interposed between the row decoder region and the second contact region, the row decoder region extending to be adjacent to the third contact region.

4. The semiconductor memory device of claim 3, further comprising:
a first lower conductive line disposed between the first pass transistor and the first gate stack structure, the first lower conductive line connecting the first conductive pattern and the first pass transistor to each other;
a second lower conductive line disposed between the second pass transistor and the first gate stack structure, the second lower conductive line connecting the second conductive pattern and the second pass transistor to each other;
a row decoder disposed in the row decoder region of the semiconductor substrate; and
a third lower conductive line disposed at a level between the first pass transistor and the first gate stack structure, the third lower conductive line being connected to the row decoder.

5. The semiconductor memory device of claim 4, wherein each of the first lower conductive line, the second lower conductive line, and the third lower conductive line extends to overlap with the vertical conductive line.

6. The semiconductor memory device of claim 5, further comprising a plurality of conductive contact structures disposed between a level at which the vertical conductive line is disposed and a level at which the first to third lower conductive lines are disposed,
wherein the vertical conductive line is connected to the first lower conductive line, the second lower conductive line, and the third lower conductive line via the plurality of conductive contact structures.

7. The semiconductor memory device of claim 3, further comprising:
a channel layer overlapping with the cell array region of the semiconductor substrate, the channel layer penetrating the first gate stack structure;
a memory layer between the channel layer and the first gate stack structure;
a bit line disposed between the channel layer and the semiconductor substrate, the bit line being connected to the channel layer; and
a source layer extending to overlap with the first gate stack structure and the second gate stack structure, the source layer being in contact with the channel layer.

8. The semiconductor memory device of claim 7, further comprising a vertical insulating layer extending along surfaces of the vertical conductive line, which face the first gate stack structure, the second gate stack structure, and the source layer,
wherein the vertical insulating layer is thicker than the memory layer.

9. A semiconductor memory device, comprising:
a semiconductor substrate including a peripheral circuit structure;
a vertical conductive line disposed over the semiconductor substrate, the vertical conductive line extending in a first direction on a plane parallel to the semiconductor substrate, the vertical conductive line being connected to the peripheral circuit structure;
a vertical insulating layer extending on a sidewall of the vertical conductive line; and
a first gate stack structure and a second gate stack structure, adjacent to each other in a second direction intersecting the vertical conductive line,
wherein the vertical conductive line and the vertical insulating layer are disposed between the first gate stack structure and the second gate stack structure, and
wherein each of the first gate stack structure and the second gate stack structure includes a plurality of interlayer insulating layers and a plurality of conductive patterns, which are alternately stacked over the semiconductor substrate.

10. The semiconductor memory device of claim 9, wherein the peripheral circuit structure includes a first circuit group, a second circuit group, and a third circuit group, which are connected to the vertical conductive line and are spaced apart from each other, and
wherein the vertical conductive line is configured to transmit a signal output from the third circuit group to the first circuit group and the second circuit group.

11. The semiconductor memory device of claim 10, wherein the third circuit group is configured to output the signal corresponding to a block select signal, and
wherein the first circuit group and the second circuit group are configured to transmit operating voltages to the plurality of conductive patterns of one of the first gate stack structure and the second gate stack structure in response to the block select signal.

12. The semiconductor memory device of claim 11, wherein the plurality of conductive patterns include a first local line and a second local line, which are spaced apart from each other in a direction intersecting a top surface of the semiconductor substrate,
wherein the first circuit group includes a first pass transistor connected to the first local line, and
the second circuit group includes a second pass transistor connected to the second local line, and
wherein the vertical conductive line is commonly connected to a first gate electrode of the first pass transistor and a second gate electrode of the second pass transistor.

13. The semiconductor memory device of claim 10, further comprising:
a channel layer penetrating the first gate stack structure and the second gate stack structure;
a memory layer surrounding a sidewall of the channel layer;
a bit line disposed between the peripheral circuit structure and the channel layer, the bit line being connected to the channel layer; and
a source layer extending to overlap with the first gate stack structure and the second gate stack structure, the source layer being in contact with the channel layer.

14. The semiconductor memory device of claim 13, wherein each of the channel layer and the vertical conductive line protrudes farther toward the source layer than the memory layer.

15. The semiconductor memory device of claim 13, wherein the vertical insulating layer extends between the source layer and the vertical conductive line.

16. The semiconductor memory device of claim 13, wherein the vertical insulating layer is thicker than the memory layer.

17. A semiconductor memory device comprising:
a semiconductor substrate including a first circuit group and a second circuit group, which are spaced apart from each other;
a memory cell array overlapping with the semiconductor substrate;
a vertical conductive line crossing the memory cell array, the vertical conductive line overlapping with the semiconductor substrate;
a plurality of first conductive bonding patterns disposed at a level between the semiconductor substrate and the memory cell array, the plurality of first conductive bonding patterns being respectively connected to the first circuit group and the second circuit group; and
a plurality of second conductive bonding patterns disposed at a level between the plurality of first conductive bonding patterns and the memory cell array, the plurality of second conductive bonding patterns being connected to the vertical conductive line and the memory cell array, the plurality of second conductive bonding patterns being bonded to the plurality of first conductive bonding patterns,
wherein the vertical conductive line is commonly connected to the first circuit group and the second circuit group via parts of the plurality of first conductive bonding patterns and parts of the plurality of second conductive bonding patterns.

18. The semiconductor memory device of claim 17, wherein the memory cell array includes:
a plurality of interlayer insulating layers and a plurality of conductive patterns, alternately stacked over the semiconductor substrate;
a channel layer penetrating the plurality of interlayer insulating layers and the plurality of conductive patterns; and
a memory layer surrounding a sidewall of the channel layer.

19. The semiconductor memory device of claim 18, further comprising:
a source layer in contact with the channel layer, the source layer extending to overlap with the vertical conductive line; and
a vertical insulating layer extending along surfaces of the vertical conductive line, which face the plurality of interlayer insulating layers, the plurality of conductive patterns, and the source layer.

20. The semiconductor memory device of claim 19, wherein the vertical insulating layer is thicker than the memory layer.
